(19) United States
(12) Patent Application Publication
(10) Pub. No.: US 2026/0029724 A1
(43) Pub. Date: Jan. 29, 2026

(54) DATA TRANSFER DEVICE, EXPOSURE DEVICE, DEVICE, AND DEVICE MANUFACTURING METHOD

(71) Applicant: NIKON CORPORATION, Tokyo (JP)

(72) Inventors: Masaki NISHIMURA, Tokyo (JP); Masaki KATO, Yokohama-shi (JP); Takachika SHIMOYAMA, Yokohama-shi (JP); Hiroyoshi ASAUMI, Kawasaki-shi (JP)

(73) Assignee: NIKON CORPORATION, Tokyo (JP)

(21) Appl. No.: 19/337,362

(22) Filed: Sep. 23, 2025

Related U.S. Application Data
(63) Continuation of application No. PCT/JP2024/009599, filed on Mar. 12, 2024.

(30) Foreign Application Priority Data
Mar. 28, 2023 (JP) 2023-052032

(51) Int. Cl. G03F 7/00; G06F 3/06

(52) U.S. Cl. CPC G03F 7/70508; G03F 7/70116; G03F 7/70258; G06F 3/0613; G06F 3/0647; G06F 3/0683

(57) ABSTRACT

Provided is a data transfer device used in an exposure device that exposes a substrate by controlling elements included in a spatial light modulator based on drawing data, the data transfer device includes a first processing unit that divides first data, which is the drawing data, to generate a plurality of pieces of second data, and transfer the plurality of pieces of second data, a second processing unit that includes a first storage unit including a first memory group including first memories that respectively store the plurality of pieces of second data transferred from the first processing unit, and transfers the second data from each of the first memories, and a third processing unit that includes a second storage unit that stores third data that is the second data transferred from each of the first memories, and transfers the third data to the spatial light modulator.

### CROSS-REFERENCE TO RELATED APPLICATION

This application is a continuation application of PCT/JP2024/009599, filed on Mar. 12, 2024, which claims the benefit of priority of the prior Japanese Patent Application No. 2023-052032, filed on Mar. 28, 2023, the entire contents of which are incorporated herein by reference.

### FIELD

A certain aspect of embodiments described herein relates to a data transfer device, an exposure device, a device, and a device manufacturing method.

### BACKGROUND

Conventionally, in a lithography process for manufacturing electronic devices (microdevices) such as display panels using liquid crystal or organic EL, and semiconductor elements (integrated circuits, etc.), a step-and-repeat projection exposure device (so-called stepper), a step-and-scan projection exposure device (so-called scanning stepper (also called scanner)) have been used. This type of exposure device projects and exposes a mask pattern for an electronic device onto a photosensitive layer applied to the surface of a substrate to be exposed (hereinafter, also simply referred to as a substrate) such as a glass substrate, a semiconductor wafer, a printed wiring board, or a resin film.

Since it takes time and cost to fabricate a mask substrate on which a mask pattern is fixedly formed, an exposure device using a spatial light modulator (variable mask pattern generator) such as a digital mirror device (DMD) in which a large number of micromirrors that are slightly displaced are regularly arranged instead of the mask substrate is known as disclosed in, for example, Japanese Patent Application Publication No. 2019-23748 (Patent Document 1). In the exposure device disclosed in Patent Document 1, for example, illumination light obtained by mixing light from a laser diode (LD) with a wavelength of 375 nm and light from an LD with a wavelength of 405 nm with a multimode fiber bundle is irradiated onto a digital mirror device (DMD), and the reflected light from each of a large number of micromirrors whose inclinations are controlled is projected and exposed on a substrate through an imaging optical system and a microlens array.

### SUMMARY

It is desired to stably transfer data for controlling a spatial light modulator from a storage device storing the data to a control unit of the spatial light modulator in a short time.

In a first aspect of the present disclosure, there is provided a data transfer device used in an exposure device that exposes a substrate by controlling a plurality of elements included in a spatial light modulator based on drawing data, the data transfer device including: a first processing unit that divides first data, which is the drawing data, to generate a plurality of pieces of second data, and transfer the plurality of pieces of second data; a second processing unit that includes a first storage unit including a first memory group including a plurality of first memories that respectively store the plurality of pieces of second data transferred from the first processing unit, and transfers the second data from each of the plurality of first memories; and a third processing unit that includes a second storage unit that stores third data that is the second data transferred from each of the plurality of first memories, and transfers the third data to the spatial light modulator.

In a second aspect of the present disclosure, an exposure device includes the above data transfer device; an illumination unit that illuminates the spatial light modulator controlled based on the third data transferred from the data transfer device with illumination light; and a plurality of projection units that form an image of exposure light modulated by the spatial light modulator on the substrate, wherein the plurality of projection units adjust an imaging position on the substrate for each projection unit to form an image of the exposure light on the substrate.

In a third aspect of the present disclosure, a device includes: a plurality of first memories each storing data; and a second memory that is connected to each of the plurality of first memories, and stores the plurality of pieces of data from the plurality of first memories.

In a fourth aspect of the present disclosure, a device manufacturing method includes: exposing an exposure object using the exposure device according to claim 19; and developing the exposed exposure object.

The configuration of the embodiments described below may be modified appropriately, and at least one or some of the components may be substituted for other components. Further, the constituent elements whose arrangement is not particularly limited are not limited to the arrangement disclosed in the embodiment, and can be arranged at positions where the functions can be achieved.

### BRIEF DESCRIPTION OF DRAWINGS

FIG. 1 is a block diagram illustrating a general configuration of an exposure device according to a first embodiment;

FIG. 2 is a perspective view illustrating an outline of an external configuration of a main unit of the exposure device;

FIG. 3 is a diagram illustrating an example of arrangement of projection areas of DMDs projected onto a substrate by projection units of each of exposure module groups;

FIG. 4 is a diagram for describing a state of joint exposure by each of four specific projection areas in FIG. 3;

FIG. 5 is an optical arrangement diagram illustrating a specific configuration of two exposure modules arranged in the X direction (scanning exposure direction) as viewed in the XZ plane;

FIG. 6A schematically illustrates a DMD, FIG. 6B illustrates the DMD when the power is OFF, FIG. 6C is a view for describing mirror in an ON state, and FIG. 6D is a view for describing a mirror in an OFF state;

FIG. 7 is a diagram illustrating an example of a data flow in the exposure device according to the first embodiment;

FIG. 8A is a diagram illustrating division of a plurality of micromirrors of the DMD into segments, and FIG. 8B is a diagram illustrating SLM data generated by a module PC;

FIG. 9 is a block diagram illustrating a configuration of a storage control board;

FIG. 10 is a time chart illustrating a data transmission speed to a DMD control board, a readout speed of a first memory, and a data amount in a second storage unit;

FIG. 11A is a diagram illustrating another example of the segments of the DMD, FIG. 11B is a diagram illustrating the SLM data stored in a plurality of first memories, and FIG. 11C is a diagram illustrating the SLM data transferred from the first memories;

FIG. 12 is a block diagram illustrating a configuration of a storage control board according to a second embodiment;

FIG. 13A is a conceptual diagram illustrating a procedure in the case of forming a pattern B different from a pattern A on a substrate after forming the pattern A on the substrate in the exposure device according to the first embodiment, and FIG. 13B is a conceptual diagram illustrating a procedure in the case of forming the pattern B different from the pattern A on a substrate after forming the pattern A on the substrate in the exposure device according to the second embodiment;

FIG. 14 is a diagram illustrating an outline of an exposure system according to a third embodiment;

FIG. 15A and FIG. 15B are diagrams for describing a wiring pattern formed by the exposure system according to the third embodiment;

FIG. 16A is a schematic view illustrating a wafer on which all chips are arranged at design positions, and FIG. 16B is a schematic view illustrating a wafer on which chips are arranged at positions deviated from the design positions;

FIG. 17 is a conceptual diagram of a wiring pattern formation procedure of FO-WLP in the third embodiment;

FIG. 18 is a diagram illustrating another example of a configuration of the module PC and the storage control board in the first to third embodiments;

FIG. 19A is a time chart illustrating a change in the amount of data in the second storage unit during exposure processing, and FIG. 19B is a diagram illustrating the readout speed of the first memory and the minimum data amount in the second storage unit during exposure with respect to the total amount of written data;

FIG. 20 is a functional block diagram of an abnormality detection device according to a fourth embodiment;

FIG. 21 is another example of a functional block diagram of the abnormality detection device;

FIG. 22 is a flowchart illustrating a part of a manufacturing process when a semiconductor device is manufactured; and

FIG. 23 is a flowchart illustrating a part of a manufacturing process when a liquid crystal display element is manufactured.

### DESCRIPTION OF EMBODIMENTS

Hereinafter, embodiments of the present disclosure will be described with reference to the drawings. In the following description, an XYZ orthogonal coordinate system is set, and the positional relationship of each member will be described with reference to the XYZ orthogonal coordinate system. A predetermined direction in a horizontal plane is defined as an X-axis direction, a direction orthogonal to the X-axis direction in the horizontal plane is defined as a Y-axis direction, and a direction orthogonal to each of the X-axis direction and the Y-axis direction (i.e., a vertical direction) is defined as a Z-axis direction. Further, the rotation (inclination) directions around the X axis, the Y axis, and the Z axis are defined as OX, OY, and OZ directions, respectively.

### First Embodiment

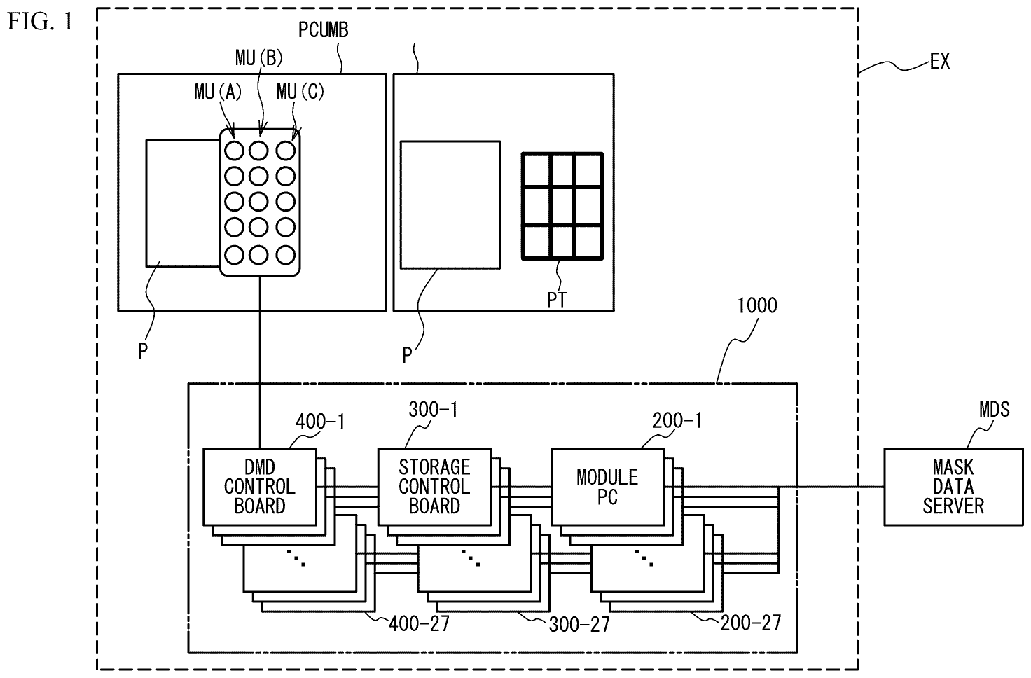

FIG. 1 is a block diagram illustrating a general configuration of an exposure device EX according to a first embodiment. The exposure device EX includes a main unit MB, a substrate exchange unit PCU, and a data transfer device 1000.

### Configuration of Main Unit MB

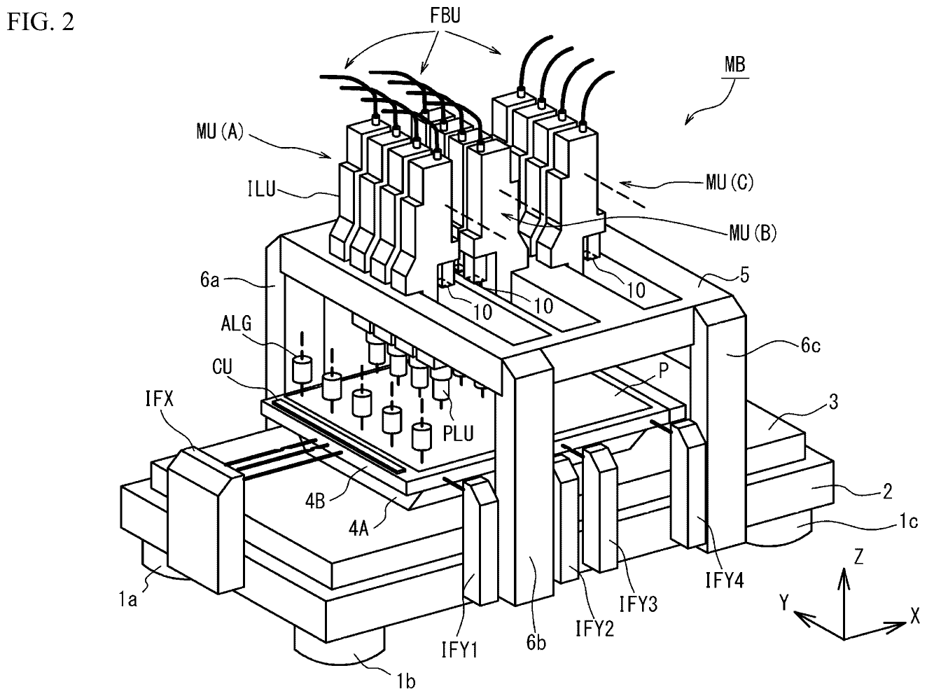

First, the configuration of the main unit MB will be described. FIG. 2 is a perspective view illustrating an outline of an external configuration of the main unit MB of the exposure device EX. The exposure device EX is a device that forms and projects an image of exposure light, whose intensity distribution in a space is dynamically modulated by a spatial light modulator (SLM), onto a substrate to be exposed. Examples of the spatial light modulator include a liquid crystal element, a digital micromirror device (DMD), and a magneto optic spatial light modulator (MOSLM). The exposure device EX according to the present embodiment includes a DMD 10 as a spatial light modulator, but may include another spatial light modulator.

In a specific embodiment, the exposure device EX is a step-and-scan projection exposure device that uses a rectangular (square) glass substrate used in a display device (flat panel display) or the like as an exposure target. The glass substrate is a substrate P for a flat panel display having at least one side length or diagonal length of 500 mm or greater and a thickness of 1 mm or less. The exposure device EX exposes a projection image of a pattern formed by the DMD 10 on a photosensitive layer (photoresist) formed on the surface of the substrate P with a constant thickness. The substrate P carried out from the exposure device EX after the exposure is sent to a predetermined process step (a film forming step, an etching step, a plating step, or the like) after the development step.

The main unit MB includes a stage device including a pedestal 2 placed on active anti-vibration units 1a, 1b, 1c, and 1d (1d is not illustrated), a surface plate 3 placed on the pedestal 2, an XY-stage 4A that is two-dimensionally movable on the surface plate 3, a substrate holder 4B that holds the substrate P by suction on the XY-stage 4A in a planar position, and laser length measuring interferometers (hereinafter, also simply referred to as interferometers) IFX and IFY1 to IFY4 that measure a two dimensional movement position of the substrate holder 4B (substrate P). Such a stage device is disclosed in, for example, U.S. Patent Application Publication No. 2010/0018950 and U.S. Patent Application Publication No. 2012/0057140.

In FIG. 2, the XY-plane of the orthogonal coordinate system XYZ is set parallel to the flat face of the surface plate 3 of the stage device, and the XY-stage 4A is set to be movable in translation within the XY-plane. In the present embodiment, the direction parallel to the X axis of the XYZ-coordinate system is set as the scanning direction of the substrate P (XY-stage 4A) during scanning exposure. The movement position of the substrate P in the X-axis direction is sequentially measured by the interferometer IFX, and the movement position in the Y-axis direction is sequentially measured by at least one (preferably two or more) of the four interferometers IFY1 to IFY4. The substrate holder 4B is configured to be slightly movable in the direction of the Z-axis perpendicular to the XY plane with respect to the XY-stage 4A and to be slightly tiltable in an arbitrary direction with respect to the XY plane, thereby actively adjusting the focus and leveling (parallelism) between the surface of the substrate P and the image plane of the projected pattern. Further, the substrate holder 4B is configured to be capable of minute rotation (θz rotation) around an axial line parallel to the Z-axis in order to actively adjust the tilt of the substrate P in the XY plane.

The main unit MB further includes an optical surface plate 5 that holds a plurality of exposure (drawing) module groups MU(A), MU(B), and MU(C), and main columns 6a, 6b, 6c, and 6d (6d is not illustrated) that support the optical surface plate 5 from the pedestal 2. Each of the exposure module groups MU(A), MU(B), and MU(C) is attached to the +Z direction side of the optical surface plate 5. Each of the plurality of exposure module groups MU(A), MU(B), and MU(C) has illumination units ILU that are attached to the +Z direction side of the optical surface plate 5 and receive illumination light from optical fiber units FBU, and projection units PLU that are attached to the −Z direction side of the optical surface plate 5 and have an optical axis parallel to the Z axis. Further, each of the exposure module groups MU(A), MU(B), and MU(C) includes DMDs 10 as a light modulator that reflects the illumination light from the illumination unit ILU toward the −Z direction and causes the illumination light to enter the projection unit PLU. The detailed configuration of the exposure module composed of the illumination unit ILU, the DMD 10 and the projection unit PLU will be described later.

A plurality of alignment systems (microscopes) ALG that detect alignment marks formed at a plurality of predetermined positions on the substrate P are attached to the −Z direction side of the optical surface plate 5 of the main unit MB. Further, a calibration reference unit CU for calibration is provided at an end portion in the −X direction on the substrate holder 4B. The calibration includes at least one of the following processes: checking (calibration) of the relative positional relationship in the XY plane of the detection field of each of the alignment systems ALG, checking (calibration) of the baseline error between each projection position of the pattern image projected from the projection unit PLU of each of the exposure module groups MU(A), MU(B), and MU(C) and the position of the detection field of each of the alignment systems ALG, and checking of the position and image quality of the pattern image projected from the projection unit PLU. Although some are not illustrated in FIG. 2, each of the exposure module groups MU(A), MU(B), and MU(C) includes nine modules arranged at regular intervals in the Y direction as an example in the present embodiment, but the number of modules may be less than nine or greater than nine. Further, in FIG. 2, the exposure modules are arranged in three rows in the X-axis direction, but the number of rows of the exposure modules arranged in the X-axis direction may be two or less, or four or more.

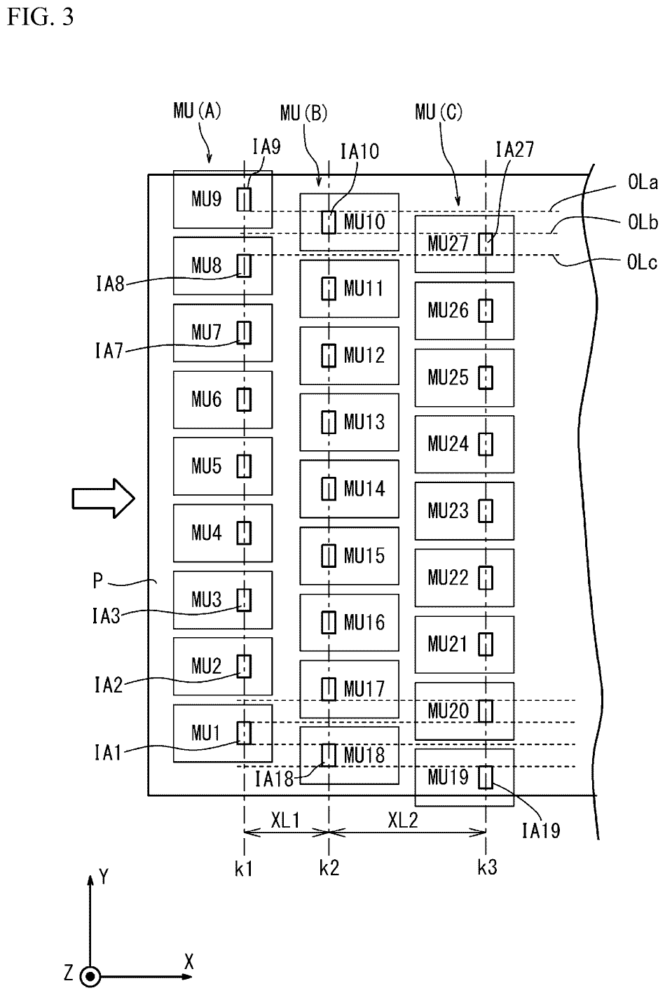

FIG. 3 is a diagram illustrating an example of arrangement of projection areas IAn of the DMDs 10 projected onto the substrate P by the projection units PLU of the exposure module groups MU(A), MU(B), and MU(C), and the orthogonal coordinate system XYZ is set in the same manner as in FIG. 2. In the present embodiment, each of the exposure module group MU(A) in the first column, the exposure module group MU(B) in the second column, and the exposure module group MU(C) in the third column, which are arranged apart from each other in the X direction, includes nine modules arranged in the Y direction. The exposure module group MU(A) includes nine modules MU1 to MU9 disposed in the +Y direction, the exposure module group MU(B) includes nine modules MU10 to MU18 disposed in the −Y direction, and the exposure module group MU(C) includes nine modules MU19 to MU27 disposed in the +Y direction. The modules MU1 to MU27 all have the same configuration, and when the exposure module group MU(A) and the exposure module group MU(B) are arranged facing each other in the X direction, the exposure module group MU(B) and the exposure module group MU(C) are arranged back-to back in the X direction.

In FIG. 3, the shapes of respective projection areas IA1, IA2, IA3, . . . , IA27 (also represented as IAn where n is 1 to 27) by the modules MU1 to MU27 are, for example, rectangles extending in the Y direction with an aspect ratio of approximately 1:2. In the present embodiment, as the substrate P is scanned in the +X direction, the joint exposure is performed between the −Y direction end of each of the projection areas IA1 to IA9 in the first column and the +Y direction end of each of the projection areas IA10 to IA 18 in the second column. Then, the areas on the substrate P that are not exposed by the projection areas IA1 to IA18 in the first and second columns are subjected to the joint exposure by the projection areas IA19 to IA27 in the third column. The center points of the projection areas IA1 to IA9 in the first column are located on a line k1 parallel to the Y axis, the center points of the projection areas IA10 to IA18 in the second column are located on a line k2 parallel to the Y axis, and the center points of the projection areas IA19 to IA27 in the third column are located on a line k3 parallel to the Y axis. The interval between the line k1 and the line k2 in the X direction is set to the distance XL1, and the interval between the line k2 and the line k3 in the X direction is set to the distance XL2.

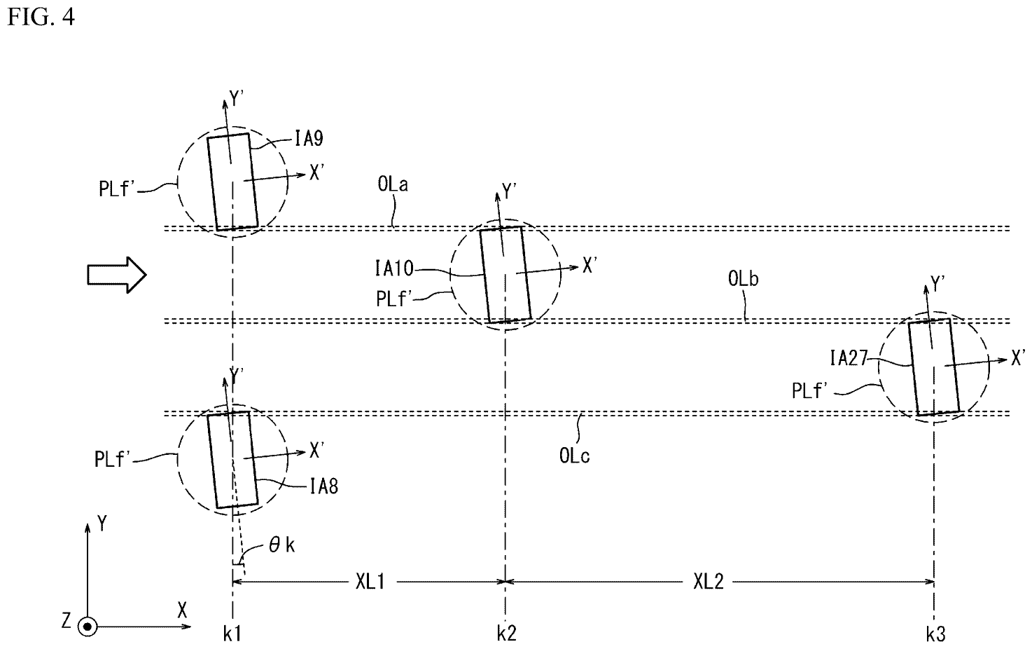

Here, when a joint portion between the −Y direction end of the projection area IA9 and the +Y direction end of the projection area IA10 is represented by OLa, a joint portion between the −Y direction end of the projection area IA10 and the +Y direction end of the projection area IA27 is represented by OLb, and a joint portion between the +Y direction end of the projection area IA8 and the −Y direction end of the projection area IA27 is represented by OLc, the state of the joint exposure will be described with reference to FIG. 4. In FIG. 4, the orthogonal coordinate system XYZ is set in the same manner as in FIG. 2 and FIG. 3, and the coordinate system X′Y′ in the projection areas IA8, IA9, IA10, and IA27 (and all other projection areas IAn) are set to be inclined by an angle θk with respect to the X axis and the Y axis (lines k1 to k3) of the orthogonal coordinate system XYZ. That is, the entire DMD 10 is inclined by an angle θk in the XY plane so that the two dimensional arrangement of a large number of micromirrors in the DMD 10 forms the coordinate system X′Y′.

The circular area containing each of the projection areas IA8, IA9, IA10, and IA27 (and all other projection areas IAn as well) in FIG. 4 represents the circular image field PLf′ of the projection unit PLU. In the joint portion OLa, the projected images of the micromirrors arranged obliquely (at the angle θk) in the −Y′ direction end of the projection area IA9 and the projected images of the micromirrors arranged obliquely (at the angle θk) in the +Y′ direction end of the projection area IA10 are set so as to overlap each other. In the joint portion OLb, the projected images of the micromirrors arranged obliquely (at the angle θk) in the −Y′ direction end of the projection area IA10 and the projected images of the micromirrors arranged obliquely (at the angle θk) in the +Y′ direction end of the projection area IA27 are set to overlap each other. Similarly, in the joint portion OLc, the projected images of the micromirrors arranged obliquely (at the angle θk) in the +Y′ direction end of the projection area IA8 and the projected images of the micromirrors arranged obliquely (at the angle θk) in the −Y′ direction end of the projection area IA27 are set to overlap each other.

### Configuration of Illumination Unit

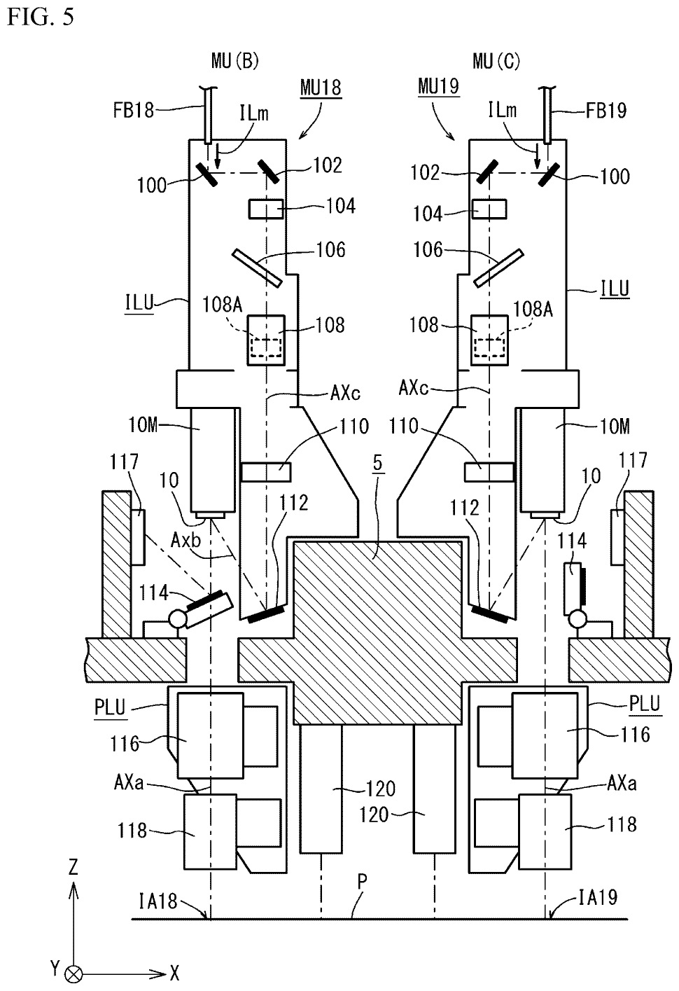

FIG. 5 is an optical arrangement diagram illustrating specific configurations of the module MU18 in the exposure module group MU(B) and the module MU19 in the exposure module group MU(C) illustrated in FIG. 2 and FIG. 3, as viewed in the XZ plane. The orthogonal coordinate system XYZ in FIG. 5 is set to be the same as the orthogonal coordinate system XYZ in FIG. 2 to FIG. 4. As is clear from the arrangement of the modules in the XY plane illustrated in FIG. 3, the module MU18 is shifted from the module MU19 by a predetermined distance in the +Y direction, and the modules are arranged back to back. Since each optical member in the module MU18 and each optical member in the module MU19 are formed of the same material and are configured in the same manner, the optical configuration of the module MU18 will be mainly described in detail here. The optical fiber unit FBU illustrated in FIG. 2 is composed of 27 optical fiber bundles FB1 to FB27 corresponding to 27 modules MU1 to MU27, respectively, illustrated in FIG. 3.

The illumination unit ILU of the module MU18 includes a mirror 100 that reflects the illumination light ILm traveling in the −Z direction from the emission end of the optical fiber bundle FB18, a mirror 102 that reflects the illumination light ILm from the mirror 100 in the −Z direction, an input lens system 104 that acts as a collimator lens, an illumination adjustment filter 106, an optical integrator 108 including a micro-fly-eye (MFE) lens 108A, a field lens, and the like, a condenser lens system 110, and an inclined mirror 112 that reflects the illumination light ILm from the condenser lens system 110 toward the DMD 10. The mirror 102, the input lens system 104, the optical integrator 108, the condenser lens system 110, and the inclined mirror 112 are arranged along an optical axis AXc parallel to the Z axis.

The fiber bundle FB18 is composed of a single optical fiber line or multiple optical fiber lines bundled together. The illumination light ILm emitted from the emission end of the optical fiber bundle FB18 (each of the optical fiber lines) is set to have a numerical aperture (NA, also referred to as a spread angle) so as to be incident without being blocked by the input lens system 104 in the subsequent stage. The position of the front focal point of the input lens system 104 is set to be the same as the position of the emission end of the optical fiber bundle FB18. Further, the position of the rear focal point of the input lens system 104 is set so that the illumination light ILm from the single or plural point light sources formed at the emission end of the optical fiber bundle FB18 is superimposed on the incident surface side of the MFE lens 108A of the optical integrator 108. Therefore, the incident surface of the MFE lens 108A is Koehler-illuminated by the illumination light ILm from the emission end of the optical fiber bundle FB18. In the initial state, the geometric center point of the emission end of the optical fiber bundle FB18 in the XY plane is located on the optical axis AXc, and the main light beam (center line) of the illumination light ILm from the point light source at the emission end of the optical fiber bundle is parallel to (or coaxial with) the optical axis AXc.

The illumination light ILm from the input lens system 104 is attenuated by the illumination adjustment filter 106 by an arbitrary value in a range of 0% to 90%, and then passes through the optical integrator 108 (MFE lens 108A, field lens, etc.) to enter the condenser lens system 110. The MFE lens 108A is formed by two-dimensionally arranging a large number of rectangular microlenses each having sides of several tens of micrometers, and the entire shape of the MFE lens 108A is set to be substantially similar to the entire shape of the mirror surface of the DMD 10 (aspect ratio is about 1:2) in the XY plane. The position of the front focal point of the condenser lens system 110 is set to be substantially the same as the position of the emission surface of the MFE lens 108A. Therefore, the illumination light from each of the point light sources formed on the emission sides of the large number of microlenses of the MFE lens 108A is converted into a substantially parallel light flux by the condenser lens system 110, reflected by the inclined mirror 112, and then superimposed on the DMD 10 to form a uniform illumination distribution. Since a surface light source in which a large number of point light sources (light converging points) are two-dimensionally and densely arranged is generated on the emission surface of the MFE lens 108A, the MFE lens 108A functions as a surface light source member.

In the module MU18 illustrated in FIG. 5, an optical axis AXc parallel to the Z-axis passing through the condenser lens system 110 is bent by the inclined mirror 112 and reaches the DMD 10, and the optical axis between the inclined mirror 112 and the DMD 10 is defined as an optical axis AXb. In the present embodiment, a neutral plane including the center point of each of the plurality of micromirrors of the DMD 10 is set parallel to the XY plane. Therefore, the angle between the normal line of the neutral plane (parallel to the Z-axis) and the optical axis AXb is the incident angle Og of the illumination light ILm with respect to the DMD 10. The DMD 10 is attached to the lower side of a mount portion 10M fixed to a support column of the illumination unit ILU. In order to finely adjust the position and orientation of the DMD 10, a fine adjustment stage is provided on the mount portion 10M, which is a combination of a parallel link mechanism and an expandable piezoelectric element as disclosed in, for example, International Publication No. 2006/120927.

### Configuration of DMD

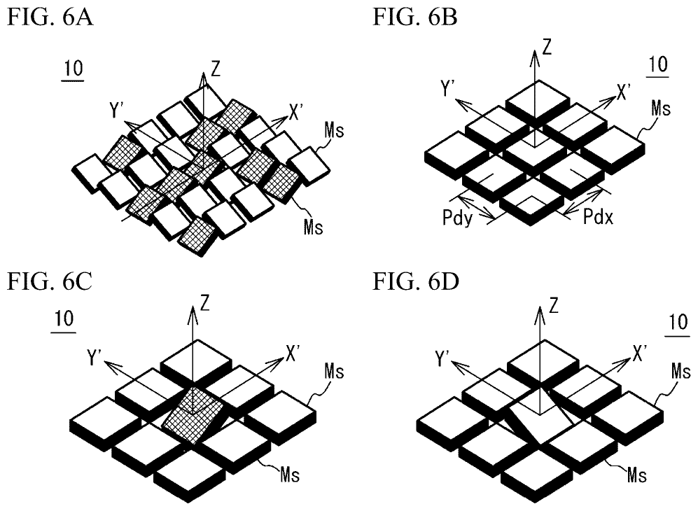

FIG. 6A schematically illustrates the DMD 10, FIG. 6B illustrates the DMD 10 when the power is OFF, FIG. 6C is a view for describing a mirror in an ON state, and FIG. 6D is a view for describing a mirror in an OFF state. In FIG. 6A to FIG. 6D, the mirror in the ON state is indicated by hatching.

The DMD 10 has a plurality of micromirrors Ms of which the reflection angles can be changed. In the present embodiment, the DMD 10 is of a roll and pitch driving type that switches between the ON and OFF states by the tilt of the micromirror Ms in the roll direction and the tilt of the micromirror Ms in the pitch direction.

As illustrated in FIG. 6B, when the power is OFF, the reflection surface of each micromirror Ms is set parallel to the X′Y′ plane. The arrangement pitch of each micromirror Ms in the X′ direction is represented by Pdx (μm), and the arrangement pitch in the Y′ direction is represented by Pdy (μm), but in practice, Pdx is set equal to Pdy.

Each micromirror Ms is tilted about the Y′ axis to be in the ON state. FIG. 6C illustrates a case where only the central micromirror Ms is in the ON state and the other micromirrors Ms are in the neutral state (neither ON nor OFF). Further, each micromirror Ms is tilted about X′ axis to be in the OFF state. FIG. 6D illustrates a case where only the central micromirror Ms is in the OFF state and the other micromirrors Ms are in the neutral state. Although not illustrated for the sake of simplicity, the micromirror Ms in the ON state is driven to be tilted at a predetermined angle from the X′Y′ plane so that the illumination light irradiated onto the micromirror Ms in the ON state is reflected in the X direction of the XZ plane. The micromirror Ms in the OFF state is driven to be tilted at a predetermined angle from the X′Y′ plane so that the illumination light irradiated onto the micromirror Ms in the OFF state is reflected in the Y direction in the YZ plane. The DMD 10 generates an exposure pattern by switching the ON and OFF states of each micromirror Ms.

The illumination light reflected by the micromirror Ms in the OFF state is absorbed by a light absorber (not illustrated).

Since the DMD 10 has been described as an example of the spatial light modulator, the spatial light modulator has been described as a reflective type that reflects the laser light, but the spatial light modulator may be a transmissive type that transmits the laser light or a diffractive type that diffracts the laser light. The spatial light modulator can spatially and temporally modulate the laser light.

Referring back to FIG. 5, the illumination light ILm irradiated onto the micromirror Ms in the ON state among the micromirrors Ms of the DMD 10 is reflected in the X direction in the XZ plane so as to be directed toward the projection unit PLU. On the other hand, the illumination light ILm irradiated onto the micromirror Ms in the OFF state among the micromirrors Ms of the DMD 10 is reflected in the Y direction in the YZ plane so as not to be directed to the projection unit PLU.

A movable shutter 114 for shielding the light reflected from the DMD 10 during the non-exposure period is provided in the optical path between the DMD 10 and the projection unit PLU so as to be inserted and removed. The movable shutter 114 is rotated to an angular position where it is retracted from the optical path during the exposure period as illustrated on the module MU19 side, and is rotated to an angular position where it is obliquely inserted into the optical path during the non-exposure period as illustrated on the module MU18 side. A reflection surface is formed on the DMD 10 side of the movable shutter 114, and the light from the DMD 10 reflected by the reflection surface is irradiated onto a light absorber 117. The light absorber 117 absorbs optical energy in the ultraviolet wavelength range (wavelength of 400 nm or less) without re-reflecting it and converts it into heat energy. Therefore, the light absorber 117 is also provided with a heat dissipation mechanism (a heat dissipation fin or a cooling mechanism). Although not illustrated in FIG. 5, the light reflected from the micromirror Ms of the DMD 10 that is in the OFF state during the exposure period is absorbed by a similar light absorber (not illustrated in FIG. 5) disposed in the Y direction (the direction perpendicular to the plane of FIG. 5) with respect to the optical path between the DMD 10 and the projection unit PLU, as described above.

### Configuration of Projection Unit

The projection unit PLU attached to the lower side of the optical surface plate 5 is configured as a both-side telecentric imaging projection lens system including a first lens group 116 and a second lens group 118 arranged along an optical axis AXa parallel to the Z axis. The first lens group 116 and the second lens group 118 are each configured to be translational in the direction along the Z-axis (optical axis Axa) by fine actuators relative to the support columns fixed to the lower side of the optical surface plate 5. The projection magnification Mp of the imaging projecting lens system composed of the first lens group 116 and the second lens group 118 is determined by the relationship between the arrangement pitch of the micromirrors on the DMD 10 and the minimum line widths (minimum pixel dimensions) Pg of the patterns projected in the projection area IAn (n=1 to 27) on the substrate P.

As an example, when the required minimum line width (minimum pixel size) Pg is 1 μm and the arrangement pitches Pdx and Pdy of the micromirrors are 5.4 μm, the projecting magnification Mp is set to approximately ⅙ in consideration of the inclination angle θk of the projection area IAn (DMD 10) in the XY plane described in FIG. 4. The imaging projecting lens system formed by the lens groups 116 and 118 forms an inverted/reversed reduced image of the entire mirror surface of the DMD 10 onto the projection area IA18 (IAn) on the substrate P.

The first lens group 116 of the projection unit PLU is finely movable in the direction of the optical axis AXa by an actuator in order to finely adjust the projecting magnification Mp (about ±several tens of ppm), and the second lens group 118 is finely movable in the direction of the optical axis AXa by an actuator in order to adjust the focus at high speed. Furthermore, in order to measure the positional change of the surface of the substrate P in the Z-axis direction with an accuracy of submicron or less, a plurality of oblique-incidence type focus sensors 120 are provided on the lower side of the optical surface plate 5. The focus sensors 120 measure the overall positional change of the substrate P in the Z-axis direction, the positional change of the partial region on the substrate P in the Z-axis direction corresponding to each of the projection areas IAn (n=1 to 27), the partial inclination change of the substrate P, or the like.

Since the projection area IAn is required to be inclined by the angle θk in the XY plane as described with reference to FIG. 4, the illumination unit ILU and the projection unit PLU are arranged so that the DMD 10 and the illumination unit ILU (at least the optical path portion between the mirror 102 and the inclined mirror 112 along the optical axis AXc) in FIG. 5 are inclined by the angle θk in the XY plane as a whole.

In the main unit MB configured as described above, the modules MUn (n=1 to 27) perform exposure processing based on data transferred from the data transfer device 1000 described later, and form a desired pattern on the substrate P.

Referring back to FIG. 1, the substrate exchange unit PCU includes a port PT, and carries out the substrate P exposed in the main unit MB described above from the main unit MB, and carries in the substrate P to be exposed next (unprocessed substrate P) to the main unit MB.

### Configuration of Data Transfer Device 1000

Next, a configuration of the data transfer device 1000 will be described. As illustrated in FIG. 1, the data transfer device 1000 includes module personal computers (PCs) 200-1 to 200-27, storage control boards 300-1 to 300-27, and DMD control boards 400-1 to 400-27.

The module PCs 200-1 to 200-27, the storage control boards 300-1 to 300-27, and the DMD control boards 400-1 to 400-27 are provided so as to correspond to the modules MU1 to MU27, respectively.

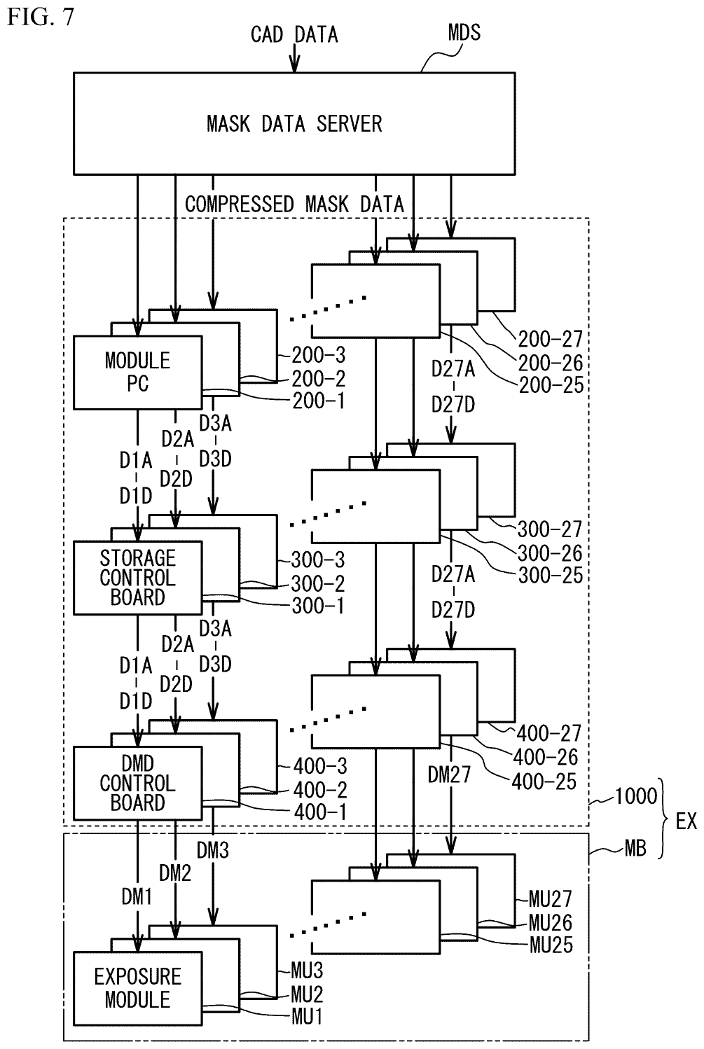

FIG. 7 is a view illustrating an example of a data flow in the exposure device EX according to the first embodiment. The module PC 200-n (n=1 to 27) is connected to a mask data server MDS. The mask data server MDS receives CAD (Computer Aided Design) data indicating a pattern to be exposed by the exposure device EX. The mask data server MDS converts the input CAD data into a bitmap (BMP) file. Since the size of the BMP file is as large as several tens of TB, for example, the mask data server MDS creates compressed mask data (drawing data) (first data) obtained by compressing the BMP file.

The module PC 200-n (n=1 to 27) downloads the compressed mask file created by the mask file server MDS. The module PC 200-n divides the downloaded compressed mask data to generate SLM data that indicates the exposure pattern to be generated by the DMD 10 of the corresponding module MUn. The SLM data may be calculated at high speed using a dedicated board such as a GPU or an FPGA, instead of or in addition to the module PC 200-n. Further, the SLM data may be calculated by a third processing unit 61 provided in the storage control board 300-n to be described later. In addition, when the FPGA is used, the function of the module PC may be included in the storage control board.

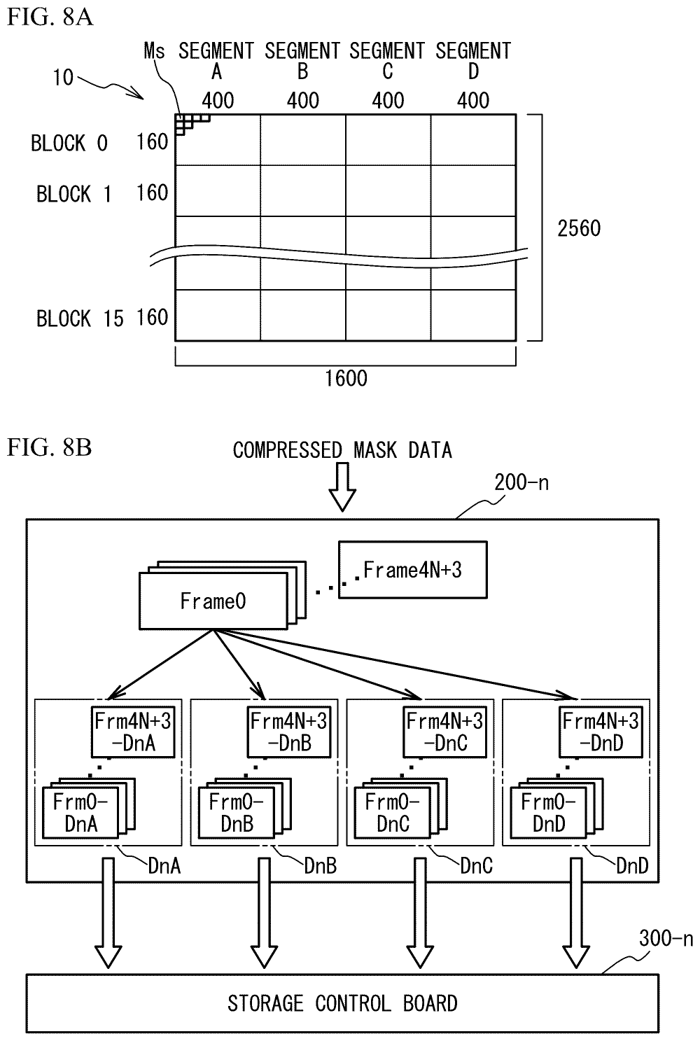

The SLM data generated by the module PC 200-n will be described. FIG. 8A is a diagram for describing the division of the micromirrors Ms of the DMD 10 into segments in the present embodiment, and FIG. 8B is a diagram for describing the SLM data generated by the module PC 200-n.

As illustrated in FIG. 8A, in the present embodiment, the DMD 10 has 2560×1600 micromirrors Ms. The module PC 200-n divides the 2560×1600 micromirrors Ms into four segments (segments A to D)×16 blocks (block 0 to block 15). The number of micromirrors Ms of the DMD 10, the number of segments, and the number of blocks are not limited to those in the present embodiment.

The module PC 200-n generates the SLM data DnA to DnD corresponding to the segments A to D of the DMD 10, respectively, and writes the SLM data DnA to DnD to the storage control board 300-n.

This will be described in more detail. The module PC 200-n (n=1 to 27) (first processing unit) creates SLM data Frame0 indicating an exposure pattern to be generated in by the DMD 10 of the module MUn at a first timing, and divides the SLM data Frame0 in correspondence with the above-described segments A to D. The data divided into segments in the SLM data Frame 0 is designated as divided data Frm0-DnA to Frm0-DnD. Then, the module PC 200-n creates SLM data Frame 1 indicating an exposure pattern to be generated by the DMD 10 of the module MUn at a second timing, and creates divided data Frm1-DnA to Frm1-DnD obtained by dividing the SLM data Frame1 in correspondence with the segments A to D. For example, when the module PC 200-n creates the SLM data up to the SLM data Frame4N+3 (N is a natural number), divided data Frm0-DnA to Frm0-DnD to divided data Frm4N+3-DnA to Frm4N+3-DnD are generated.

The module PC 200-n transfers the divided data created for each segment as the SLM data DnA to DnD to the storage control board 300-n.

Configuration of Storage Control Board 300-n (n=1 to 27)

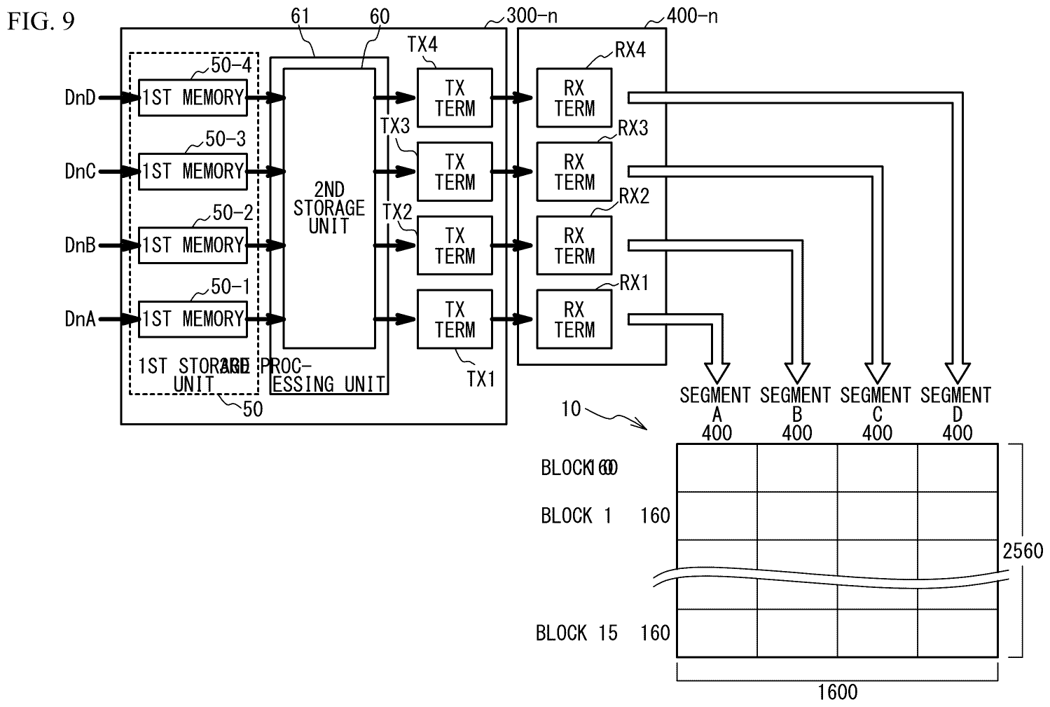

Next, a configuration of the storage control board 300-n (n=1 to 27) will be described. FIG. 9 is a block diagram illustrating a configuration of the storage control board 300-n (n=1 to 27) according to the first embodiment.

As illustrated in FIG. 9, the storage control board 300-n (n=1 to 27) (second processing unit) includes a first storage unit 50 having a plurality of first memories 50-1 to 50-4, a second storage unit 60, and transmit terminals TX1 to TX4. The second storage unit 60 is mounted on the third processing unit 61.

The first memories 50-1 to 50-4 of the first storage unit 50 are provided to correspond to the respective segments described in FIG. 8A, and store the SLM data DnA to DnD transferred from the module PC 200-n (n=1 to 27), respectively. More specifically, the first memory 50-1 stores the SLM data DnA of the segment A, the first memory 50-2 stores the SLM data DnB of the segment B, the first memory 50-3 stores the SLM data DnC of the segment C, and the first memory 50-4 stores the SLM data DnD of the segment D.

The second storage unit 60 reads the SLM data DnA to DnD from the first memories 50-1 to 50-4, temporarily stores the SLM data DnA to DnD, and transmits (transfers) the temporarily stored SLM data DnA to DnD to the DMD control board 400-n.

Referring back to FIG. 7, the DMD control board 400-n (n=1 to 27) converts the received SLM data DnA to DnD into a format displayable by the DMD 10 of the module MUn to generate data DMn, and transmits the data DMn to the module MUn.

The module MUn selectively drives the micromirrors Ms of the DMD 10 based on the received data DMn to generate the exposure pattern corresponding to the data DMn, and projects and exposes the exposure pattern onto the substrate P.

Next, the operation of the storage control board 300-n (n=1 to 27) will be described in detail with reference to FIG. 9. In the present embodiment, the first memories 50-1 to 50-4 of the storage control board 300-n operate in parallel. That is, the first memories 50-1 to 50-4 can independently transfer the SLM data DnA to DnD to the second storage unit 60 without being affected by the other first memories. By providing the first memories 50-1 to 50-4 and parallelizing the first memories 50-1 to 50-4, it is possible to shorten the transfer time of the SLM data (for example, the SLM data Frame0) even in a case where the first memories are used. In the present embodiment, since the four first memories 50-1 to 50-4 are provided, the SLM data Frame0 can be transferred in a time that is approximately ¼ of the time for transferring the SLM data Frame0 from one first memory, for example.

Before the start of exposure, the SLM data DnA to DnD stored in the first memories 50-1 to 50-4 are read out to the second storage unit 60 and stored in the second storage unit 60. When the exposure is started, the SLM data DnA to DnD stored in the second storage unit 60 are transmitted to receive terminals RX1 to RX4 of the DMD control board 400-n (n=1 to 27) via the transmit terminals TX1 to TX4, respectively, and the SLM data DnA to DnD are sequentially read from the first memories 50-1 to 50-4 to the second storage unit 60. The transfer speed of the second storage unit 60 is slower than the transfer speeds of the first memories 50-1 to 50-4. In addition, even when the transfer speed of the second storage unit 60 is higher than the transfer speeds of the first memories 50-1 to 50-4, the present embodiment is effective. In the present embodiment, the number of the transmission terminals TX1 to TX4 and the number of the receive terminals RX1 to RX4 are the same as the number of the segments, but the number of the transmit terminals TX1 to TX4 and the number of the receive terminals RX1 to RX4 are not limited to this.

Here, the reason why the storage control board 300-n (n=1 to 27) includes the second storage unit 60 will be described.

In a case where the second storage unit 60 is not provided and the SLM data is transmitted (transferred) from the first memory 50-m (m=1 to 4) to the DMD control board 400-n, when the readout speed of the first memory 50-m is slower than the data transmission speed of the SLM data to the DMD control board 400-n, the readout speed of the first memory 50-m is insufficient, and part of the SLM data is lost. Further, when the first memory 50-m is in the Busy state, data transfer from the first memory 50-m may be stopped. Thus, when the SLM data is directly transferred from the first memory 50-m to the DMD control board 400-n, there is a risk that part of the SLM data transmitted to the DMD control board 400-n is lost, and the stability of the exposure device EX is significantly reduced.

Therefore, in the present embodiment, the second storage unit 60 is provided so that the transfer of the SLM data is not affected even when the readout speed of the first memory 50-m varies and decreases. That is, the second storage unit 60 functions as a buffer.

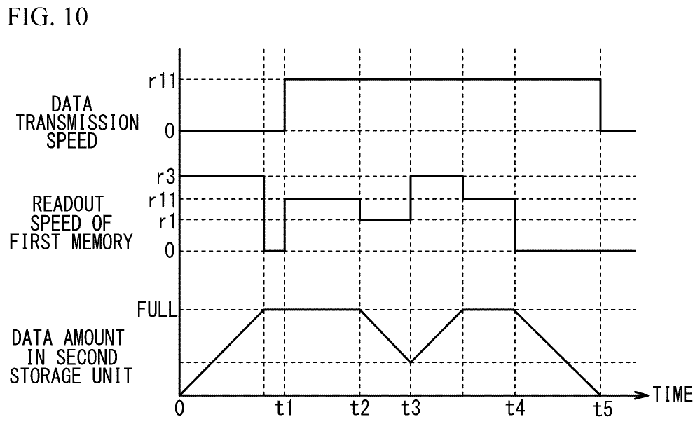

FIG. 10 is a time chart illustrating a data transmission speed to the DMD control board 400-n (n=1 to 27), a readout speed of the first memory 50-m (m=1 to 4), and a data amount in the second storage unit 60. In FIG. 10, time t1 is the time at which exposure is started, and time t5 is the time at which the exposure ends.

Before time t1, that is, before the start of exposure, a predetermined amount (FULL) of SLM data is stored in the second storage unit 60.

When exposure is started at time t1, the SLM data in the second storage unit 60 is read and transmitted to the DMD control board 400-n. The transmission speed at this time is denoted by r11.

Since the readout speed r11 of the first memory 50-m is the same as the transmission speed r11 between time t1 and time t2, the amount of data in the second storage unit 60 remains FULL. At time t2, when the readout speed of the first memory 50-m becomes a speed r1 slower than the transmission speed r11, the amount of data transmitted from the second storage 60 becomes larger than the amount of data read from the first memory 50-m to the second storage 60, and thus the amount of data in the second storage 60 decreases. However, since the data in the second storage unit 60 is not depleted, no SLM data is lost, and the exposure failure does not occur.

Thereafter, when the readout speed of the first memory 50-m becomes higher than the transmission speed r11 again at time t3, the amount of data in the second storage unit 60 increases. When the reading of data from the first memory 50-m is completed at time t4, the reading of the data from the first memory 50-m to the second storage unit 60 is stopped, and thus the amount of the data in the second storage unit 60 decreases and becomes 0 at time t5 when the exposure is completed.

In this manner, by parallelizing the first memories 50-1 to 50-4, the time required for transferring the SLM data is reduced, and by providing the second storage unit 60, the SLM data can be stably transmitted to the DMD control board 400-n (n=1 to 27) without causing any loss of the SLM data. This can prevent exposure failure due to a loss of SLM data.

Next, the minimum capacity required for the second storage unit 60 will be described. In the following description, the amount of data with which the exposure can be performed without data loss while the exposure device is performing exposure in consideration of the presence and absence of a decrease in the speed of the first memory, of the capacity of the second storage unit 60, will be referred to as a buffer capacity. The minimum required buffer capacity can be calculated based on the readout speed of the first memory 50-m (m=1 to 4) and the data transmission speed to the DMD control board 400-n (n=1 to 27).

When the data transfer speed to the DMD control board is greater than the nominal value of the readout speed of the first memory, the minimum required buffer capacity is calculated by the following equation (1).

$$Minimum required buffer capacity = \{ ( Data transfer speed to the DMD control board - Transfer speed when the readout speed of the first memory decreases \} ) \times Time during which the readout speed of the first memory decreases \} \qquad ( 1 )$$

When the data transfer speed to the DMD control board is less than the nominal value of the readout speed of the first memory, the minimum required buffer capacity is calculated by the following equation (2).

$$Minimum required buffer capacity = \{ Data transfer speed to the DMD control board - Nominal value of the readout speed of the first memory \times Scanning time \} + \{ ( Data transfer speed to the DMD control board - Transfer speed when the readout speed of the first memory decreases ) \times Time during which the readout speed of the first memory decreases \} \qquad ( 2 )$$

In the equations (1) and (2), the “Transfer speed when the readout speed of the first memory decreases” may be “Transfer speed assuming a decrease in the readout speed of the first memory”, and the “Time during which the readout speed of the first memory decreases” may be the “Assumed value of the time during which the readout speed of the first memory decreases”.

The minimum required buffer capacity is determined as appropriate based on the specifications of the exposure device EX and the specifications of the first memory to be mounted.

As described above in detail, according to the first embodiment, the data transfer device 1000 is a data transfer device used in the exposure device EX that exposes the substrate P by controlling a plurality of micromirrors Ms included in the DMD 10 based on drawing data, and includes the module PC 200-n that generates the SLM data DnA to DnD (n=1 to 27) by dividing the compressed mask data that is the drawing data, and transfers a plurality of pieces of the SLM data DnA to DnD, the storage control board 300-n that includes a plurality of the first memories 50-1 to 50-4 that store the SLM data DnA to DnD transferred from the module PC 200-n, and transfers the SLM data DnA to DnD from the first memories 50-1 to 50-4, respectively, and the second storage unit 60 that stores the SLM data DnA to DnD transferred from the first memories 50-1 to 50-4 and transfers the SLM data DnA to DnD to the DMD 10.

By providing the first memories 50-1 to 50-4 operating in parallel, the time required for transferring the SLM data can be reduced, and the second storage unit 60 absorbs the variation in the readout speed of the first memories 50-1 to 50-4, so that the SLM data can be stably transmitted to the DMD control board 400-n (n=1 to 27) without causing a loss of the SLM data. This can prevent exposure failure due to a loss of part of the SLM data.

In addition, in the first embodiment, the storage control board 300-n (n=1 to 27) transfers the SLM data DnA to DnD to the second storage unit 60 before the exposure of the substrate P, and the second storage unit 60 stores the SLM data DnA to DnD before the exposure of the substrate P. This prevents part of the SLM data to be transmitted to the DMD control board 400-n from being lost at the start of exposure, and prevents exposure failure from occurring.

In addition, in the first embodiment, the storage control board 300-n (n=1 to 27) transfers part of the SLM data DnA to DnD to the second storage unit 60 before the exposure of the substrate P. The buffer capacity of the second storage unit 60 requires less capacity than in a case where all of the SLM data DnA to DnD are transferred to the second storage unit 60.

In the first embodiment, the module PC 200-n divides the plurality of micromirrors Ms into a plurality of segments A to D to generate the SLM data DnA to DnD, and generates the SLM data DnA to DnD corresponding to respective segments A to D from the compressed mask data. Accordingly, since the SLM data DnA to DnD can be transferred from the first memories 50-1 to 50-4 operating in parallel, respectively, the transfer time of the SLM data can be reduced.

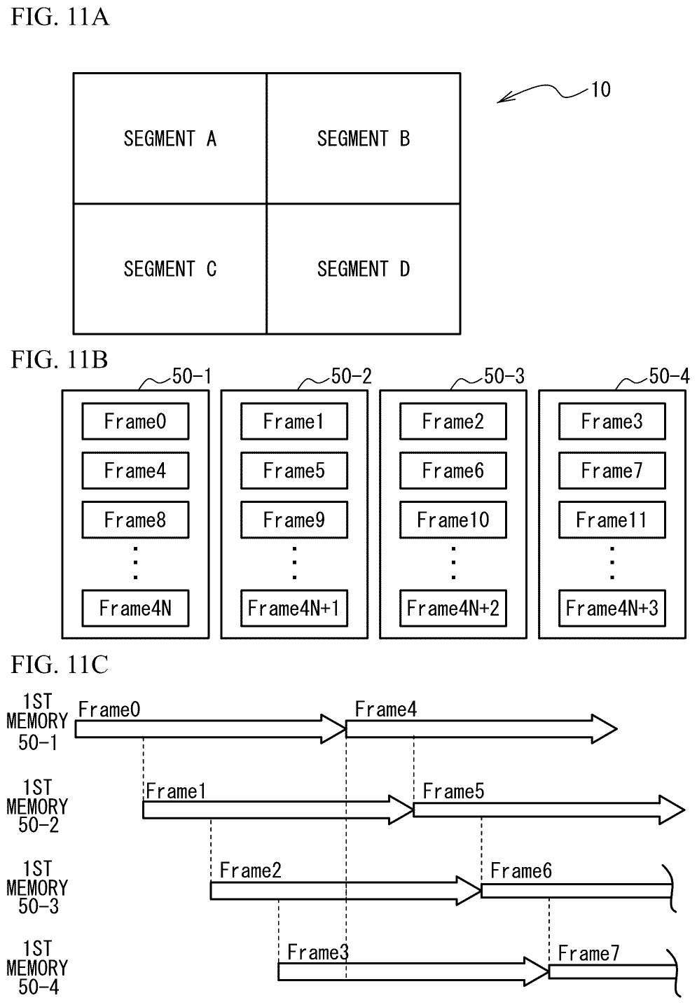

In the first embodiment, the first memories 50-1 to 50-4 are provided corresponding to a plurality of segments of the DMD 10, but the method of dividing the DMD 10 into segments is not limited to that illustrated in FIG. 8A. For example, as illustrated in FIG. 11A, the DMD 10 may be divided into four segments. The number of segments into which the DMD 10 is divided is not limited to four, and may be two, three, or five or more.

In the first embodiment, the SLM data Frame0 indicating the exposure pattern to be generated by the plurality of micromirrors Ms at first control timing is divided corresponding to the segments A to D obtained by dividing the micromirrors Ms of the DMD 10, and the divided data Frm0-DnA to Frm0-DnD are stored in the first memories 50-1 to 50-4, respectively, but this does not intend to suggest any limitation.

The SLM data Frame0 indicating the exposure pattern to be generated by the micromirrors Ms at the first control timing may be stored in, for example, the first memory 50-1 without being divided, and the SLM data Frame1 indicating the exposure pattern to be generated by the micromirrors Ms at second control timing may be stored in, for example, the first memory 50-2 without being divided.

In particular, as illustrated in FIG. 11B, the first memory 50-1 may store the SLM data Frame0, Frame4, Frame8, . . . , Frame4N (N is a positive integer), the first memory 50-2 may store the SLM data Frame1, Frame5, Frame9, . . . , Frame4N+1, the first memory 50-3 may store the SLM data Frame2, Frame6, Frame10, . . . , Frame4N+2, and the first memory 50-4 may store the SLM data Frame3, Frame7, Frame11, . . . , Frame4N+3.

In this case, the module PC 200-n (n=1 to 27) generates SLM data such that the SLM data Frame0 indicating an exposure pattern to be generated by the micromirrors Ms of the DMD 10 at the first control timing (first control data with which the micromirrors Ms are controlled at the first control timing) and the SLM data Frame2 indicating an exposure pattern to be generated by the micromirrors Ms of the DMD 10 at the second control timing (second control data with which the micromirrors Ms are controlled at the second control timing) to each of the first memories 50-m (m=1 to 4).

FIG. 11C is a diagram schematically illustrating reading of the SLM data from the first memories 50-1 to 50-4. As illustrated in FIG. 11C, first, the SLM data Frame0 for the first control timing is read from the first memory 50-1. At the timing when one fourth of the SLM data Frame0 is read out, the reading of the SLM data Frame1 from the first memory 50-2 is started. Thereafter, the reading of the SLM data Frame2 from the first memory 50-3 is started at the timing when one fourth of the SLM data Frame1 has been read, and the reading of the SLM data Frame3 from the first memory 50-4 is started at the timing when one fourth of the SLM data Frame2 has been read.

In this manner, the SLM data indicating the exposure pattern to be generated by the micromirrors Ms of the DMD 10 may be transmitted in a time-division manner. Even with this configuration, the transfer time of the SLM data corresponding to the entire pattern to be formed on the substrate P by one scan (exposure process) can be shortened compared to the case where one first memory is provided. In a case where the SLM data is transmitted in a time division manner, the SLM data is merged in the second storage unit 60.

### Second Embodiment

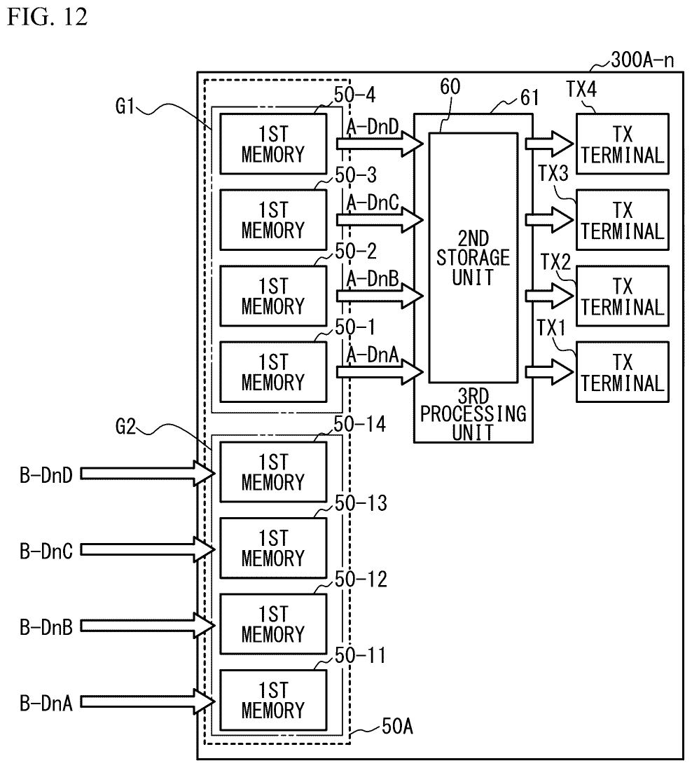

Next, a second embodiment will be described. In the second embodiment, the configuration of the storage control board 300A-n (n=1 to 27) is different from that of the storage control board 300-n (n=1 to 27) according to the first embodiment. FIG. 12 is a block diagram illustrating a configuration of a storage control board 300A-n according to the second embodiment.

A first storage unit 50A provided in the storage control board 300A-n according to the second embodiment includes a first memory group G1 including the first memories 50-1 to 50-4, and a second memory group G2 including first memories 50-11 to 50-14. The second storage unit 60 is configured to be able to switch a connection destination between the first memory group G1 and the second memory group G2.

In the second embodiment, for example, the SLM data A-DnA to A-DnD for forming a pattern A on the substrate P, which are stored in the first memories 50-1 to 50-4 of the first memory group G1, are read out to the second storage unit 60, and the SLM data B-DnA to B-DnD for forming a pattern B (next lot) different from the pattern A are written to the first memories 50-11 to 50-14 of the second memory group G2 while the exposure processing is being performed. That is, the reading of the SLM data A-DnA to A-DnD from the first memories 50-1 to 50-4 of the first memory group G1 and the writing of the SLM data B-DnA to B-DnD to the first memories 50-11 to 50-14 of the second memory group G2 are performed in parallel. In the present embodiment, the SLM data is written to the first memories 50-11 to 50-14 of the second memory group G2 during exposure processing, but the SLM data may be written during alignment of the substrate or calibration of the exposure device. Also in the first embodiment, the SLM data may be transferred to the first memories 50-1 to 50-4 during alignment of the substrate or calibration of the exposure device.

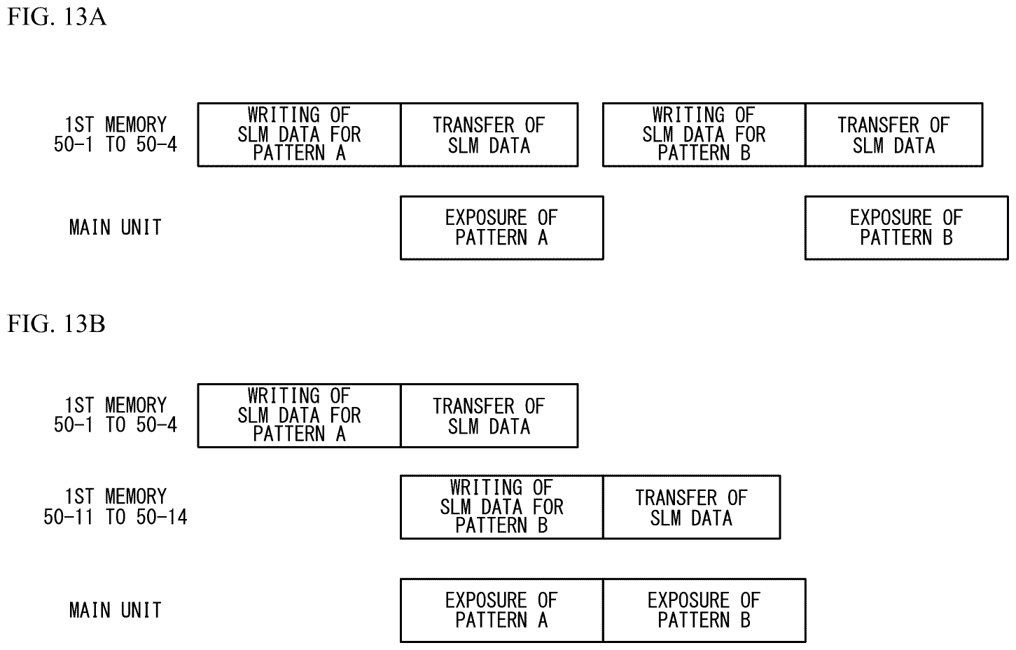

FIG. 13A is a conceptual diagram illustrating a procedure in the case of forming the pattern B different from the pattern A on a substrate after forming the pattern A on the substrate in the exposure device EX according to the first embodiment. In FIG. 13A, the SLM data for the pattern A generated by the module PC 200-n (n=1 to 27) is written in the first memories 50-1 to 50-4 of the first memory group G1, and then the exposure process of the pattern A is started. During the exposure processing of the pattern A, the first memories 50-1 to 50-4 are used to transfer the SLM data from the first memories 50-1 to 50-4 to the second storage unit 60, and thus the SLM data of the pattern B cannot be written to the first memories 50-1 to 50-4. Therefore, since the process of writing the SLM data of the pattern B to the first memories 50-1 to 50-4 can be performed after the transfer of the SLM data of the pattern A is completed, as illustrated in FIG. 13A, for example, the process of writing the SLM data of the pattern B to the first memories 50-1 to 50-4 is started after the exposure process of the pattern A. The process of writing the SLM data of the pattern B to the first memories 50-1 to 50-4 may be started immediately after the transfer of the SLM data of the pattern A is completed.

FIG. 13B is a conceptual diagram illustrating a procedure in the case of forming the pattern B different from the pattern A on a substrate after forming the pattern A on the substrate in the exposure device EX including the storage control board 300A-n (n=1 to 27) according to the second embodiment.

In FIG. 13B, the SLM data of the pattern A generated in the module PC 200-n (n=1 to 27) is written in the first memories 50-1 to 50-4 of the first memory group G1, and then the exposure process of the pattern A is started. During the exposure processing of the pattern A, the connection destination of the second storage unit 60 is the first memories 50-1 to 50-4 of the first memory group G1. As described above, during the exposure processing of the pattern A, although data cannot be written in the first memories 50-1 to 50-4, the first memories 50-11 to 50-14 of the second memory group G2 are not in use, and thus the SLM data can be written in the first memories 50-11 to 50-14 of the second memory group G2. Therefore, in the second embodiment, the writing of the SLM data of the pattern B to the first memories 50-11 to 50-14 of the second memory group G2 is executed in parallel with the transfer of the SLM data to the second storage unit 60 and the exposure processing of the pattern A.

When the exposure processing of the pattern A is completed, the connection destination of the second storage unit 60 is changed to the first memories 50-11 to 50-14 of the second memory group G2, and the SLM data is read out from the first memories 50-11 to 50-14 to the second storage unit 60 and the exposure processing of the pattern B is performed.

In this manner, by providing a plurality of memory groups each including a plurality of first memories, the exposure process and the process of writing the SLM data to the first memories can be performed in parallel, and therefore the throughput of the exposure device EX as a whole can be improved.

As described above in detail, according to the second embodiment, the storage control board 300A-n includes the first memory group G1 including a plurality of the first memories 50-1 to 50-4 and the second memory group G2 including a plurality of the first memories 50-11 to 50-14, the second memory group G2 being different from the first memory group G1. While the SLM data A-DnA to A-DnD of the pattern A stored in the first memories 50-1 to 50-4 of the first memory group G1 are being transferred to the second storage unit 60, the module PC 200-n writes the SLM data B-DnA to B-DnD of the pattern B different from the pattern A into the first memories 50-11 to 50-14 of the second memory group G2. This allows the process of writing the SLM data into the first memory, which is time consuming, to be performed behind the exposure process, thereby improving the throughput of the exposure device EX.

### Third Embodiment

In a third embodiment, a case will be described in which a rewiring layer that connects pads of semiconductor chips is formed using the exposure device EX in the manufacture of a package of a semiconductor device called a fan out wafer level package (FO-WLP) or a fan out plate level package (FO-PLP).

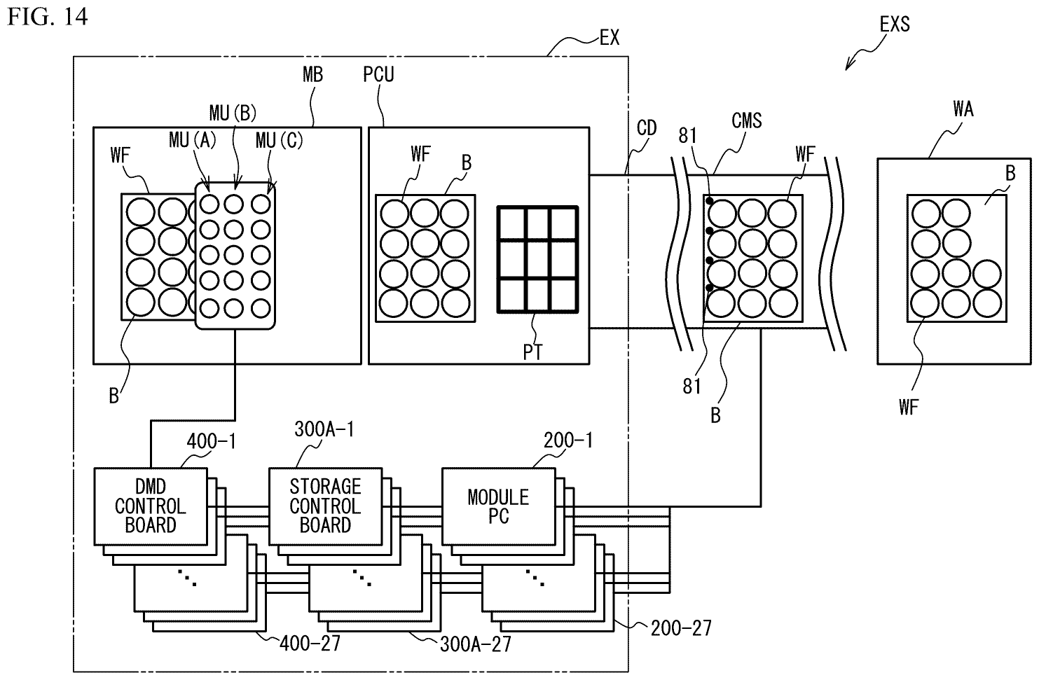

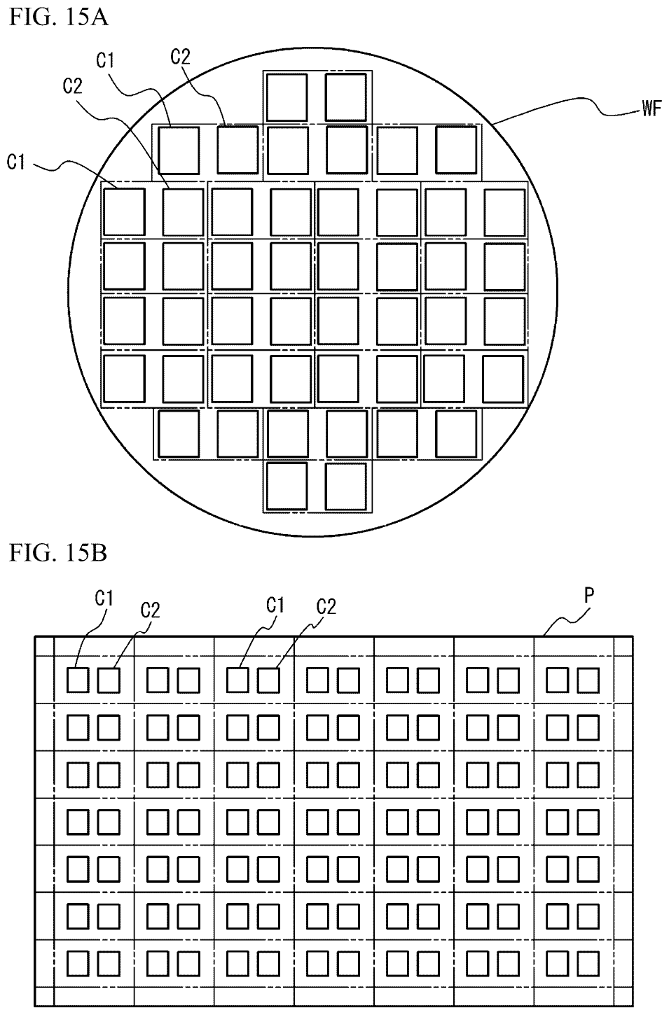

FIG. 14 is a view illustrating an outline of an exposure system EXS according to the third embodiment. The exposure system EXS is a system for forming a wiring pattern that connects between semiconductor chips (hereinafter referred to as chips) arranged on a wafer WF as illustrated in FIG. 15A or between chips arranged on a substrate P as illustrated in FIG. 15B.

In the present embodiment, a wiring pattern connecting between a chip C1 and a chip C2 included in each of sets of a plurality of chips (indicated by a two dot chain line) disposed on the wafer WF or the substrate P. In the present embodiment, the number of chips included in each set is two, but is not limited thereto, and may be three or more.

Hereinafter, a case of forming a wiring pattern connecting chips arranged on the wafer WF will be described.

As illustrated in FIG. 14, the exposure system EXS includes a wafer placement device WA, a chip measurement station CMS, a coater/developer device CD, and the exposure device EX. In the third embodiment, the exposure device EX includes the storage control board 300A-n according to the second embodiment.

The wafer placement device WA attaches a plurality of wafers WF, on which chips are arranged, to the base substrate B. The base substrate B to which the wafers WF are bonded by the wafer placement device WA is carried into the chip measurement station CMS.

The chip measurement station CMS includes a plurality of measurement microscopes 81, and measures the positions of the chips in different sets. Here, the positions of the chips in different sets measured by the measurement microscopes 81 may be the positions of the chips in different sets on the same wafer WF or the positions of the chips in each set on different wafers WF. In the present embodiment, the measurement microscopes 81 measure the positions of the chips in each set on different wafers WF, respectively.

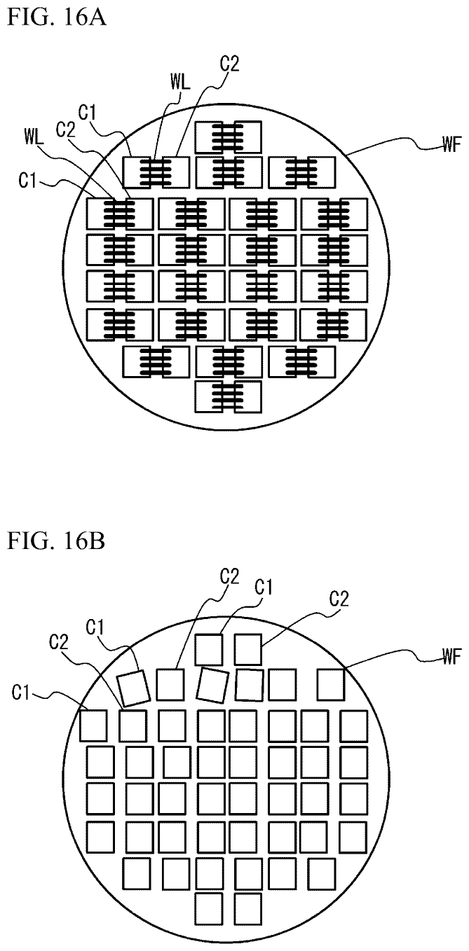

Here, the reason why the positions of the chips are measured in the chip measurement station CMS will be described. FIG. 16A is a schematic view illustrating the wafer WF in a state where all the chips are arranged at their designed positions (hereinafter, referred to as design positions). As illustrated in FIG. 16A, the wiring pattern WL connecting the chip C1 and the chip C2 is exposed (formed) by the exposure device EX. Here, in the FO-WLP, since the chips are fixed on the wafer WF with a molding material such as resin, the positions of the individual chips may be shifted from the design positions as illustrated in FIG. 16B. In this case, when the wiring pattern is exposed by controlling the DMD 10 using the SLM data (hereinafter referred to as “design value data”) indicating the wiring patterns connecting the chips at the design positions, the wiring patterns may be misaligned with the positions of the pads, and a connection defect or a short circuit may occur.

Therefore, in the present embodiment, wiring pattern data in which part of the design value data is corrected is created based on the measurement results of the positions of the chips included in each of the sets of the plurality of chips arranged on the wafer WF.

The measurement results of the positions of the chips are transmitted to the module PC 200-n (n=1 to 27). The module PC 200-n (n=1 to 27) stores therein design value data in advance. The module PC 200-n creates wiring pattern data based on the measurement results of the chip positions received from the chip measurement station CMS. The wiring pattern data created by the module PC 200-n is stored in a memory group different from the memory group in which the wiring pattern data being used to control the exposure of the substrate currently being exposed is stored. That is, when the wiring pattern data being used to control the exposure of the wafer WF currently being exposed is stored in the first memories 50-1 to 50-4 of the first memory group G1, the module PC 200-n stores (transfers) the created wiring pattern data in the first memories 50-11 to 50-14 of the second memory group G2.

The wafers WF the measurement of the positions of the chips on which is completed are carried into the coater/developer device CD together with the base substrate B, and after a photosensitive resist is applied, the wafers WF are carried into the port PT of the substrate exchange unit PCU. Thereafter, the wafer WF is placed on the substrate holder 4B of the XY stage 4A together with the base substrate B.

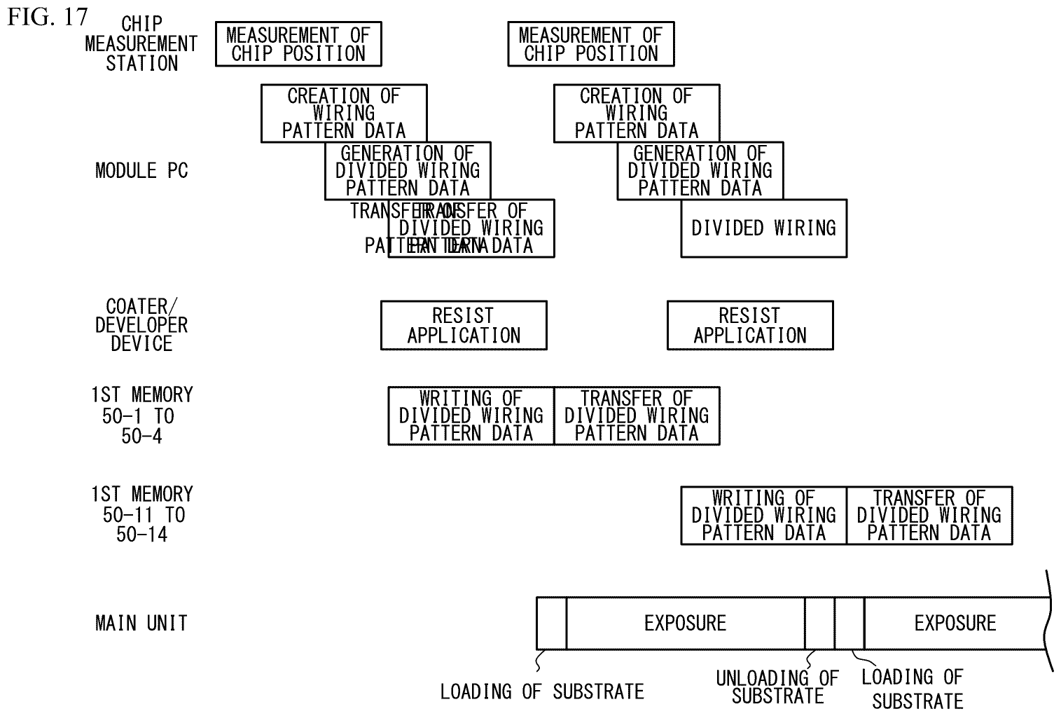

FIG. 17 is a conceptual diagram of a wiring pattern formation procedure of the FO-WLP in the third embodiment.

As illustrated in FIG. 17, in the present embodiment, when the chip positions are measured in the chip measurement station CMS, the module PC 200-n creates the wiring pattern data based on the measurement results of the chip positions, and generates the divided wiring pattern data by dividing the created wiring pattern data for each segment. The module PC 200-n transfers the divided wiring pattern data to the first memories 50-1 to 50-4. As a result, the divided wiring pattern data is written to the first memories 50-1 to 50-4. The divided wiring pattern data stored in the first memories 50-1 to 50-4 are sequentially transferred to the DMD control board 400-n in accordance with the start of exposure of the wafer WF.

While the main unit MB is performing the exposure process, the chip measurement station CMS starts measuring the chip positions of the wafer WF to be exposed next by the main unit MB. The module PC 200-n creates wiring pattern data based on the measurement results of the chip positions, and generates divided wiring pattern data by dividing the created wiring pattern data for each segment. The module PC 200-n transfers the divided wiring pattern data to the first memories 50-11 to 50-14. The divided wiring pattern data stored in the first memories 50-11 to 50-14 is sequentially transferred to the DMD control board 400-n in accordance with the start of exposure of the wafer WF on the substrate holder 4B.

As described above, by providing the first memory group G1 (the first memories 50-1 to 50-4) and the second memory group G2 (the first memories 50-11 to 50-14), the time for the measurement of the chip position and the processing of the creation and transfer of the wiring pattern data can be hidden in the time for the exposure processing. This can improve the throughput in the formation of the wiring pattern of the FO-WLP. Such parallel processing is particularly effective when it takes time to create, transfer, and store the wiring pattern data.

In the first to third embodiments, as the first memories included in the first storage unit 50 or 50A, solid state drives (SSDs), dynamic random access memories (DRAMs), flash memories, hard disk drives (HDDs), magnetic random access memories (MRAMs), RAID storages, or network storages may be used. As the second storage unit 60, a high bandwidth memory (HBM), a dynamic random access memory (DRAM), or a static random access memory (SRAM) may be used.

The present embodiment is not limited to FO-WLP or FO-PLP, and can also be used when manufacturing a semiconductor chip and a flat panel display. Since a semiconductor chip and a flat panel display are manufactured by overlapping several to several tens of different patterns in the chip C1, it is necessary to perform accurate overlay exposure in the chip C1. When the chip positions are measured in the chip measurement station CMS, the module PC 200-n creates the wiring pattern data based on the measurement results of the chip positions, and generates the divided wiring pattern data by dividing the created wiring pattern data for each segment. This allows the module MUn to perform exposure in the correct position.

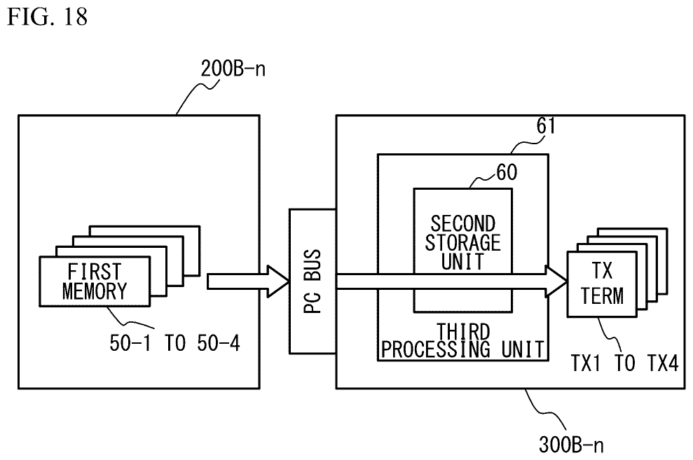

In addition, in a case where the PC bus is sufficiently fast, as illustrated in FIG. 18, the first memories 50-1 to 50-4 may be provided in the module PC 200B-n instead of a storage control board 300B-n.

### Fourth Embodiment

In a fourth embodiment, abnormality detection of the first memory 50-m (m=1 to 4, 11 to 14) used in the first to third embodiments will be described. When there is an error in the data stored in the first memory 50-m (m=1 to 4, 11 to 14), there is a case where sufficient exposure quality cannot be obtained, such as a case where the width of the exposed pattern becomes narrow. In addition, when the readout speed of the first memory decreases, the amount of data in the second storage unit 60 decreases, and when the remaining amount of data in the second storage unit 60 becomes “0”, the data is depleted and an exposure failure occurs. Therefore, in order to avoid such a situation, it is desirable to prevent the various characteristics of the first memory from not satisfying the conditions necessary for execution of the exposure processing during the exposure processing, and to enable the first memory to be replaced at the timing of maintenance or the like.

In general, the life of the first memory such as an SSD is defined by TBW (Total Bytes Written), and is defined as the total amount of written data that can be correctly held for one year in a state where the power is turned off.

However, in the first memory 50-m (m=1 to 4, 11 to 14) used in the exposure device EX, since the SLM data is written in the first memory 50-m in the initial processing of the lot, the condition of “data can be correctly held for one year” of the TBW is excessive, and it is sufficient if the data can be correctly held temporarily (for example, during the processing time of one lot). In addition, in order to prevent the data in the second storage unit 60 from being depleted due to a decrease in the readout speed of the first memory, it is necessary to maintain a predetermined readout speed of the first memory that is not defined in the TBW.

From the above, the total amount of written data that satisfies the following two conditions is defined as the life of the first memory in the exposure device EX according to the present embodiment.

(1) Data can be normally held for the processing time of one lot or more.

(2) A predetermined readout speed of the first memory can be maintained.

In the following description, in order to distinguish from the TBW, the total amount of written data representing the lifetime of the first memory in the exposure device EX according to the first to third embodiments will be described as a special TBW.

### Method of Determining Special TBW

Next, a method of determining the special TBW will be described.

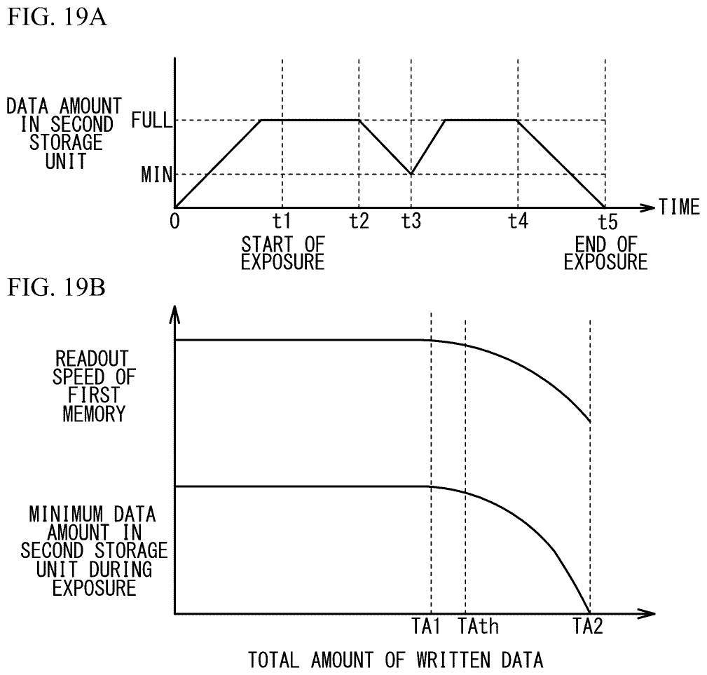

FIG. 19A is a time chart illustrating a change in the amount of data in the second storage unit 60 during the exposure process, and FIG. 19B is a diagram illustrating the readout speed of the first memory with respect to the total amount of written data and the minimum amount of data in the second storage unit 60 during the exposure.

As illustrated in FIG. 19A, while the readout speed of the first memory exceeds the data transfer speed from the second storage unit 60 (between time t1 and time t2) after the exposure processing is started at time t1, the amount of the data in the second storage unit 60 is maintained at FULL. Then, for example, when the readout speed of the first memory decreases or the reading from the first memory is temporarily stopped at time t2 and the amount of the data transferred from the first memory to the second storage unit 60 becomes smaller than the amount of the data transferred from the second storage unit 60, the amount of the data in the second storage unit 60 decreases. Then, at time t3, when the readout speed of the first memory exceeds the data transfer speed from the second storage unit 60 again, the amount of the data in the second storage unit 60 increases. In this manner, the amount of data in the second storage unit 60 varies during the exposure processing. The minimum value MIN of the amount of data in the second storage unit 60 during the period from the start of exposure to the completion of the transfer of all the SLM data in the first memory to the second storage unit 60 (the period from time t1 to time t4) is defined as the minimum data amount.

As illustrated in FIG. 19B, it is considered that the readout speed of the first memory is kept substantially constant while the total amount of written data is smaller than the first amount TA1, and starts to gradually decrease when the total amount of written data exceeds the first amount TA1.

As a result, the minimum data amount in the second storage 60 is substantially constant until the total amount of written data reaches the first amount TA1, but gradually decreases when the total amount of written data exceeds the first amount TA1, and becomes 0 when the total amount of written data reaches the second amount TA2. When the minimum data amount becomes 0, the data in the second storage unit 60 is depleted, and thus an exposure failure occurs. Therefore, it is desirable to replace the first memory when the total amount of written data is less than the second amount TA2.

In the present embodiment, therefore, the total amount of written data and the minimum amount of data in the second storage unit 60 during the exposure process are acquired in the endurance test, and the total amount of written data (second amount TA2) in which the second storage unit 60 is depleted is acquired. Thereafter, to be on the safe side, for example, the total amount of written data TAth lower than the second amount TA2 by a predetermined ratio (for example, 20% to 30%) is set as the special TBW. Therefore, the special TBW is set as the lifetime of each of the first memories 50-m used in the exposure device EX according to the present embodiment. Theoretically, the value of the special TBW is greater than or equal to the value of the TBW.

Next, an abnormality detection device for detecting an abnormality or a replacement timing of the first memory 50-m (m=1 to 4, 11 to 14) will be described. The abnormality detection device is provided in, for example, the data transfer device 1000.

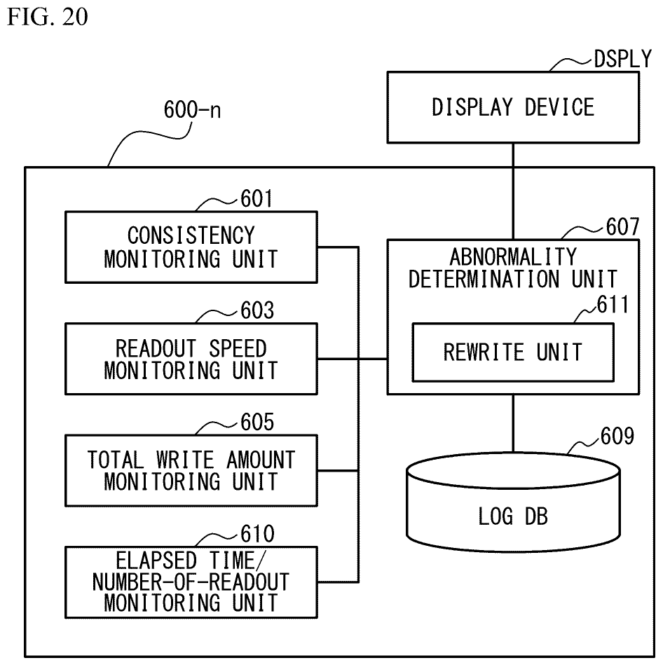

FIG. 20 is a functional block diagram of an abnormality detection device 600-n (n=1 to 27) according to the present embodiment. In the present embodiment, the abnormality detection devices 600-n (n=1 to 27) are provided corresponding to the modules MUn (n=1 to 27), respectively.

The abnormality detection device 600-n (n=1 to 27) includes a consistency monitoring unit 601, a readout speed monitoring unit 603, a total write amount monitoring unit 605, an elapsed time/number-of-readout monitoring unit 610, an abnormality determination unit 607, a log DB 609, and the like.

The log DB 609 stores logs that record various conditions, setting values, and measurement values during the exposure processing of the substrate, the timing at which the abnormality determination unit 607 detects an abnormality of the first memory 50-m (m=1 to 4, 11 to 14), and the like.

The consistency monitoring unit 601 checks whether the data written in the first memory 50-m (m=1 to 4, 11 to 14) is correct. In the present embodiment, the consistency monitoring unit 601 checks whether the data written in the first memory 50-m (m=1 to 4, 11 to 14) is correct by using a cyclic redundancy check (CRC) widely used as error detection codes.

Specifically, the consistency monitoring unit 601 stores the SLM data and the CRC code calculated from the SLM data together when the data is transferred from the module PC 200-n (n=1 to 27) to the first memory 50-m (m=1 to 4, 11 to 14). When the following data (1), (2). or (3) is read, the CRC code recalculated from the read SLM data is compared with the read CRC code to check the consistency of the data. Alternatively, the consistency of the data is checked by comparing the data transferred from the module PC 200-n (n=1 to 27) to the first memory 50-m (m=1 to 4, 11 to 14) with the read following data (1), (2), or (3).
(1) Data transferred from the first memory 50-m (m=1 to 4, 11 to 14)
(2) Data Transferred from the second storage unit 60
(3) Data transferred from the DMD control board 400-n (n=1 to 27) to the DMD 10

More specifically, when the data is transferred from the module PC 200-n (n=1 to 27) to the first memory 50-m (m=1 to 4, 11 to 14), the consistency monitoring unit 601 stores the SLM data and the CRC code calculated from the SLM data together. When the above data (1), (2), or (3) is read, the CRC code recalculated from the read SLM data is compared with the read CRC code, or the data transferred from the module PC 200-n (n=1 to 27) is compared with the read data (1), (2), or (3), and the code error rate is calculated. In other words, the consistency monitoring unit 601 compares the data before being stored in the storage control board 300-n with the read data (1), (2), or (3), and monitors the presence or absence of a different signal. The consistency monitoring unit 601 outputs the calculated code error rate to the abnormality determination unit 607.

The readout speed monitoring unit 603 monitors whether the readout speed of the first memory 50-m (m=1 to 4, 11 to 14) is maintained at a predetermined speed. In the present embodiment, the readout speed monitoring unit 603 monitors the readout speed of the first memory by monitoring the minimum value (minimum data amount) of the remaining amount of data in the second storage unit 60 during the exposure processing. The readout speed monitoring unit 603 outputs the minimum data amount of the second storage unit 60 during the exposure processing to the abnormality determination unit 607. The readout speed monitoring unit 603 may monitor the remaining amount of data in the second storage unit 60 in real time or at predetermined intervals.

The total write amount monitoring unit 605 monitors the total amount of data written to each of the first memories 50-m (m=1 to 4, 11 to 14), and outputs it to the abnormality determination unit 607.

The elapsed time/number-of-readout monitoring unit 610 monitors the writing time of data in each of the first memories 50-m (m=1 to 4, 11 to 14) or the number of times of reading data from each of the first memories 50-m (m=1 to 4, 11 to 14), and outputs the writing time of data or the number of times of reading data to the abnormality determination unit 607. In the first memory 50-m (m=1 to 4, 11 to 14), the time during which the SLM data is read at high speed becomes shorter when the SLM data is transferred to the second storage unit 60. Therefore, the elapsed time/number-of-readout monitoring unit 610 monitors the elapsed time from the end of writing of the SLM data to the first memory 50-m (m=1 to 4, 11 to 14).

The abnormality determination unit 607 compares the code error rate, the minimum data amount (readout speed of the first memory), the total amount of written data, and the elapsed time after the end of writing of the SLM data to the first memory 50-m (m=1 to 4, 11 to 14) with the respective threshold values.

For example, when the code error rate is equal to or higher than a predetermined threshold value BERth (Bit Error Rate), the abnormality determination unit 607 determines that the first memory 50-m (m=1 to 4, 11 to 14) is required to be replaced. In this case, in the present embodiment, the abnormality determination unit 607 stores the timing at which the code error rate becomes equal to or greater than the threshold value BERth in the log DB 609. The abnormality determination unit 607 may output an alert when the code error rate is equal to or greater than a predetermined threshold value BERth. The threshold value BERth is set to a value such that a desired exposure quality can be maintained.

The abnormality determination unit 607 determines that the first memory 50-m (m=1 to 4, 11 to 14) needs to be replaced when the minimum data amount is equal to or less than a predetermined threshold value MDAth. In this case, in the present embodiment, the abnormality determination unit 607 stores, in the log DB 609, not only the minimum data amount but also the timing at which the minimum data amount becomes equal to or less than the predetermined threshold value MDAth. The abnormality determination unit 607 may output an alert when the minimum data amount is equal to or less than a predetermined threshold value MDAth.

In addition, when the total amount of written data of the first memory 50-m (m=1 to 4, 11 to 14) exceeds the special TBW described above, the abnormality determination unit 607 determines that the first memory 50-m (m=1 to 4, 11 to 14) needs to be replaced. In this case, in the present embodiment, the abnormality determination unit 607 stores the timing at which the total amount of written data exceeds the special TBW in the log DB 609. The abnormality determination unit 607 may output an alert when the total amount of written data exceeds the special TBW.

In addition, the abnormality determination unit 607 may output an alert when an elapsed time after the writing of the SLM data to the first memory 50-m (m=1 to 4, 11 to 14) is completed exceeds a threshold time. A rewrite unit 611 included in the abnormality determination unit 607 may write the SLM data again to the first memory 50-m (m=1 to 4, 11 to 14).

When the total amount of the SLM data written to the first memory 50-m (m=1 to 4, 11 to 14) increases, the time during which the first memory 50-m (m=1 to 4, 11 to 14) can correctly store data becomes shorter. Therefore, the number of times and the timing of rewriting of the SLM data to the first memory 50-m (m=1 to 4, 11 to 14) by the rewrite unit 611 are determined and controlled by the abnormality determination unit 607 based on the number of times of writing of the SLM data to the first memory 50-m (m=1 to 4, 11 to 14) monitored by the elapsed time/number-of-readout monitoring unit 610 and the total elapsed time after writing.

The alert may be output by outputting a message to a display device DSPLY such as a liquid crystal display provided in the exposure device EX, or by displaying part of data stored in the log DB 609 on the display device DSPLY or printing out the part of data. The alert may be output each time the processing of one substrate is completed, or may be output for each lot. When the alert is output for each lot, the alert indicating that there is a substrate in which an error has occurred may be output.

As described above in detail, according to the fourth embodiment, the abnormality detection device 600-n (n=1 to 27) provided in the data transfer device 1000 includes the readout speed monitoring unit 603 that monitors the data amount of the SLM data stored in the second storage unit 60. This makes it possible to determine whether the data in the second storage unit 60 is depleted during the exposure processing.

In addition, according to the fourth embodiment, provided is the log DB 609 that stores the timing when the data amount of the SLM data stored in the second storage unit 60 becomes equal to or less than the threshold value MDAth, the timing when the transfer speed difference between the transfer speed of the SLM data (second data) from each first memory 50-m (m=1 to 4, 11 to 14) and the transfer speed of the SLM data (third data) transferred from the second storage unit 60 becomes equal to or less than a threshold value, or the timing (the number of frames) when the amount of data in the second storage unit 60 becomes 0. This makes it possible to check the timing at which the amount of data in the second storage unit 60 becomes equal to or less than the threshold value MDAth. In addition, since the settings and the state of each device during the exposure process are also recorded in the log DB 609, it is possible to analyze the situation when the amount of data in the second storage unit 60 becomes equal to or less than the threshold value MDAth. Further, the information for determining the timing of replacement of the first memory 50-m (m=1 to 4) can be provided to the user of the exposure device EX and the maintenance person.

According to the fourth embodiment, the abnormality detection device 600-n includes the abnormality determination unit 607 that displays a warning (alert) on the display device DSPLY (display screen) included in the exposure device EX at the timing when the data amount of the SLM data stored in the second storage unit 60 becomes equal to or less than the predetermined value MDAth, or the transfer speed difference between the transfer speed of the SLM data from each first memory 50-m (m=1 to 4, 11 to 14) and the transfer speed of the SLM data transferred from the second storage unit 60 becomes equal to or less than the predetermined value, or when the amount of data in the second storage unit 60 is 0. This allows the operator of the exposure device EX to know the timing at which the first memory 50-m needs to be replaced.

According to the fourth embodiment, the abnormality detection device 600-n includes the total write amount monitoring unit 605 that monitors the total data amount of the SLM data stored in each of the plurality of first memories 50-m (m=1 to 4, 11 to 14). This makes it possible to determine whether the total amount of written data exceeds the special TBW.

Further, according to the fourth embodiment, even after the total data amount of the SLM data stored in each of the plurality of first memories 50-m (m=1 to 4, 11 to 14) exceeds the TBW set in each of the first memories 50-m, each of the first memories 50-m can correctly hold the SLM data in each of the first memories 50-m for a predetermined period (for example, a processing period of one lot). Thereby, the first memory 50-m can be used for a period longer than the lifetime defined by the TBW.

According to the fourth embodiment, a value (special TBW) equal to or larger than the TBW is set as the lifetime of each of the first memories 50-m. Since the special TBW is larger than the TBW, the replacement interval of the first memory 50-m can be made longer than in a case where the first memory 50-m is replaced with reference to the TBW. Therefore, the lifetime cost of the exposure device EX can be reduced.

According to the fourth embodiment, the abnormality detection device 600-n includes the log DB 609 that records the total amount of the data stored in each of the first memories 50-m and stores the timing at which the total amount of data becomes equal to or greater than the threshold value (special TBW). This makes it possible to check the timing at which the total amount of written data becomes equal to or larger than the threshold value (special TBW). Further, the information for determining the replacement timing of the first memory 50-m (m=1 to 4) can be provided to the user or maintenance person of the exposure device EX.

In addition, according to the fourth embodiment, the abnormality detection device 600-n includes the consistency monitoring unit 601 that compares the SLM data before being stored in the storage control board 300-n with the SLM data transferred from the storage control board 300-n to calculate the code error rate (monitors the presence or absence of different signals). This makes it possible to check whether the consistency of the data is maintained.

In addition, according to the fourth embodiment, the consistency monitoring unit 601 compares the SLM data before being stored in the storage control board 300-n with the SLM data transferred from the second storage unit 60 to calculate the code error rate (monitors the presence or absence of different signals). This makes it possible to check whether the consistency of the data is maintained. According to the fourth embodiment, the abnormality detection device 600-n includes the log DB 609 that stores the timing at which the code error rate measured by the consistency monitoring unit 601 becomes equal to or greater than the threshold value BERth. This makes it possible to check the timing at which the code error rate becomes equal to or higher than the threshold value BERth. Further, the information for determining the replacement timing of the first memory 50-m (m=1 to 4) can be provided to the user or maintenance person of the exposure device EX.

According to the fourth embodiment, the abnormality detection device 600-n includes the abnormality determination unit 607 that displays a warning (alert) on the display device DSPLY when the code error rate measured by the consistency monitoring unit 601 is equal to or greater than the threshold value BERth. This allows the operator of the exposure device EX to know the timing of replacement of the first memory 50-m.

In the fourth embodiment, the special TBW is determined based on the minimum data amount in the second storage unit 60, but this does not intend to suggest any limitation. When there is a correlation between the total amount of written data and the code error rate, the special TBW may be determined based on the code error rate. For example, when there is a relationship such that the code error rate increases when the total amount of written data exceeds the first amount TA1, the total amount of written data at which the code error rate exceeds the threshold value may be set as the special TBW. The special TBW may be determined by using both the minimum data amount in the second storage unit 60 and the code error rate.

In the fourth embodiment, the abnormality detection device 600-n may include at least two of the consistency monitoring unit 601, the readout speed monitoring unit 603, or the total write amount monitoring unit 605.

In the fourth embodiment, the temperature in the vicinity of the second storage unit 60 and the temperature in the vicinity of the first memory may be measured. At least one of an operation guarantee temperature or a performance guarantee temperature is provided to each component from a manufacturer. For example, since there is a possibility that the first memory or the second storage unit 60 does not operate normally when the first memory or the second storage unit 60 is used at a temperature outside the operation guarantee temperature, an error (alert) may be output when the temperature in the vicinity of the second storage unit 60 and the temperature in the vicinity of the first memory are outside the respective operation guarantee temperatures.

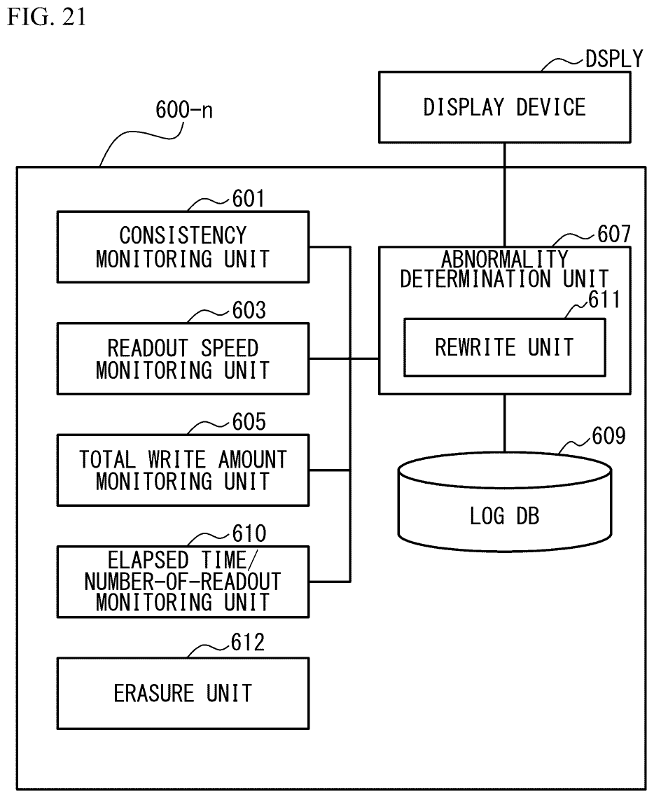

In the first to fourth embodiments, there is a case where the SLM data with which the exposure has been done remains in the first memory 50-m (m=1 to 4, 11 to 14), and in such a case, the garbage collection process is started inside the first memory 50-m (m=1 to 4, 11 to 14) irregularly and asynchronously. When the garbage collection process starts during exposure, the transfer speed of the SLM data from the first memory 50-m (m=1 to 4, 11 to 14) may decrease or the transfer of the SLM data may be temporarily stopped. In order to prevent this phenomenon, as illustrated in FIG. 21, the abnormality detection device 600-n may include an erasure unit 612 that erases the SLM data with which the exposure has been done stored in the first memory 50-m (m=1 to 4, 11 to 14). The erasure unit 612 may erase the SLM data with which the exposure has been done stored in the first memory 50-m (m=1 to 4, 11 to 14) while the lot is switched from the lot being processed in which a plurality of substrates are processed to the next lot to be processed or during the calibration time of the device.

In the first to fourth embodiments, when the first memory 50-1 of the first memories 50-m (m=1 to 4, 11 to 14) becomes unusable, the SLM data DnA that was to be stored in the first memory 50-1 is divided and stored in the remaining first memories 50-2 to 50-4. This can reduce downtime during which the exposure device cannot be used. This is not limited to a case where one first memory 50-m (m=1 to 4, 11 to 14) becomes unusable, and the same applies to a case where a plurality of first memories 50-m (m=1 to 4, 11 to 14) become unusable.

In the first to fourth embodiments, each first memory 50-m (m=1 to 4, 11 to 14) can store the same SLM data at different addresses in each first memory 50-m (m=1 to 4, 11 to 14). Specifically, the SLM data DnA is stored in two or more different addresses (first address and second address) in the first memory 50-1. When the data transfer speed of the SLM data DnA from the first address of the first memory 50-1 to the second storage unit 60 is slow for some reason, the transfer source is changed from the first address to the second address during the data transfer, and the SLM data DnA is transferred from the second address to the second storage unit 60. This prevents a delay in the data transfer speed. When the transfer source is changed from the first address to the second address, the data to be transferred from the second address is preferably the SLM data starting from the end of the part of the SLM data that has been transferred from the first address.

In the first to fourth embodiments, since the correction of the exposure position (imaging position) is performed in each of the modules MU1 to 27, the correction of the SLM data for the exposure position adjustment is not necessary. The exposure position can be adjusted by adjusting the position of the lens included in each of the modules MU1 to 27. Therefore, the same SLM data can be continuously used even for different substrates and different scan (product) regions. This eliminates the need for a data transfer process for each substrate, and as a result, the time for data transfer can be reduced, and the device operable time can be increased. Further, if exposure data is transferred for each substrate, the data transfer must be performed even during exposure, and the DMD cannot be operated at high speed. This is because, although the DMD is moved at high speed, data transfer is not performed in time, and as a result, exposure may not be performed. Furthermore, when the present method is used, a high-speed and inexpensive memory having a large capacity can be used as the first memory 50-m (m=1 to 4, 11 to 14).

In the first to fourth embodiments, when a nonvolatile memory such as an SSD or an HDD is used as the first memory 50-m (m=1 to 4, 11 or 14), the data transfer speed from the first memory 50-m (m=1 to 4, 11 or 14) to the second storage unit 60 may be slower than the reference data transfer speed. This is because the data transfer speed may be reduced when data is repeatedly stored at the address of a specific memory element of the first memory 50-m (m=1 to 4, 11 to 14) used to store the SLM data. In such a case, the first memory 50-m (m=1 to 4, 11 to 14) stores the address of the memory element having a low data transfer speed, and stores the SLM data transferred from the module PC at the address of the memory element different from the address of the memory element having a low data transfer speed. Thereafter, the first memory 50-m (m=1 to 4, 11 to 14) transfers the SLM data to the second storage unit 60 from the address of the memory element after the change. This prevents deterioration in data transfer speed.

The first to fourth embodiments can be applied to an exposure device used for manufacturing a liquid crystal display element, an exposure device used for manufacturing a display including semiconductor elements and transferring a device pattern onto a semiconductor substrate, an exposure device used for manufacturing a thin-film magnetic head and transferring a device pattern onto a ceramic wafer, an exposure device used for manufacturing an imaging element such as a CCD, and the like.

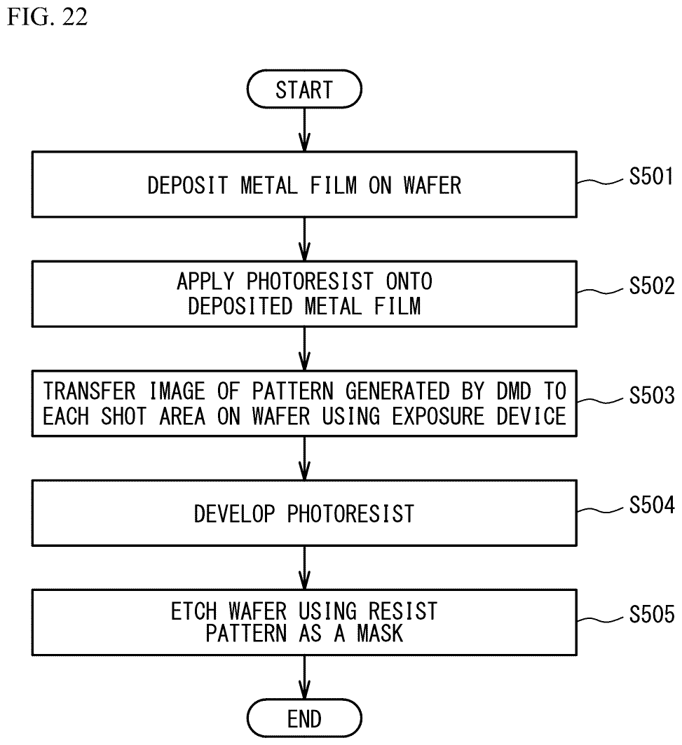

Next, an embodiment of a method of manufacturing a microdevice using the exposure device according to the first to fourth embodiments in a lithography process will be described. FIG. 22 is a flowchart illustrating a part of a manufacturing process when a semiconductor device as a microdevice is manufactured. First, in step S501 of FIG. 22, a metal film is deposited on wafers of one lot. In the next step S502, a photoresist is applied on the metal film on the wafers of the one lot. Thereafter, in step S503, the exposure device EX illustrated in FIG. 1 is used to sequentially expose and transfer the image of the pattern generated by the DMD 10 onto each shot area on the wafers of one lot.

Thereafter, in step S504, the photoresist on the wafers of the one lot is developed (developing step), and then in step S505, etching is performed on the wafers of the one lot using the resist pattern as a mask, whereby a circuit pattern corresponding to the pattern generated by the DMD 10 is formed in each shot area on each wafer. Thereafter, a circuit pattern of a further upper layer is formed, and the like, thereby manufacturing a device such as a semiconductor element. According to the above-described semiconductor device manufacturing method, semiconductor devices having an extremely fine circuit pattern can be obtained with high throughput.

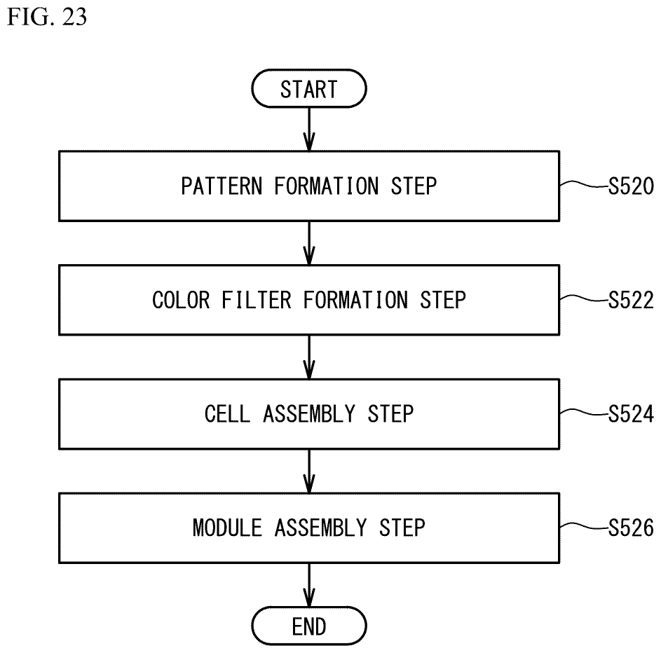

In each of the exposure devices, a liquid crystal display element as a microdevice can be obtained by forming a predetermined pattern (circuit pattern, electrode pattern, or the like) on the substrate P. An example of the method in this case will be described below with reference to the flowchart of FIG. 23. FIG. 23 is a flowchart illustrating a part of a manufacturing process when a liquid crystal display element as a microdevice is manufactured.

In a pattern formation step S520 in FIG. 23, a so-called photolithography process is performed in which a pattern generated by the DMD 10 is transferred and exposed onto a photosensitive substrate (a glass plate or the like coated with a resist) using the exposure device EX of the present embodiment or the like. Through this photolithography process, a predetermined pattern including a large number of electrodes and the like is formed on the photosensitive substrate. Thereafter, the exposed substrate is subjected to various steps such as a developing step, an etching step, and a reticle peeling step, whereby a predetermined pattern is formed on the substrate, and the process proceeds to the next color filter formation step S522.

Next, in the color filter formation step S522, a color filter is formed in which a large number of sets of three dots corresponding to R (Red), G (Green), and B (Blue) are arranged in a matrix, or a plurality of sets of filters of three stripes of R, G, and B are arranged in the horizontal scanning line direction. Then, after the color filter formation step S522, cell assembly step S524 is executed. In the cell assembly step S524, a liquid crystal panel (liquid crystal cell) is assembled using the substrate having the predetermined pattern obtained in the pattern formation step S520, the color filter obtained in the color filter formation step S522, and the like.

In the cell assembly step S524, for example, liquid crystals are injected between the substrate having the predetermined pattern obtained in the pattern formation step S520 and the color filter obtained in the color filter formation step S522, thereby manufacturing a liquid crystal display panel (liquid crystal cell). Thereafter, in module assembly step S526, various components such as an electric circuit for performing a display operation of the assembled liquid crystal panel (liquid crystal cell), a backlight, and the like are attached to complete a liquid crystal display device. According to the above-described method for manufacturing a liquid crystal display element, a liquid crystal display element having an extremely fine circuit pattern can be obtained with high throughput.

The above embodiments are preferred examples. However, the present disclosure is not limited to this, and various modifications can be made without departing from the scope of the present disclosure, and arbitrary constituent features may be combined.

What is claimed is:

1. A data transfer device used in an exposure device that exposes a substrate by controlling a plurality of elements included in a spatial light modulator based on drawing data, the data transfer device comprising:
a first processing unit that divides first data, which is the drawing data, to generate a plurality of pieces of second data, and transfer the plurality of pieces of second data;
a second processing unit that includes a first storage unit including a first memory group including a plurality of first memories that respectively store the plurality of pieces of second data transferred from the first processing unit, and transfers the second data from each of the plurality of first memories; and
a third processing unit that includes a second storage unit that stores third data that is the second data transferred from each of the plurality of first memories, and transfers the third data to the spatial light modulator.

2. The data transfer device according to claim 1, wherein a transfer speed of the third data by the third processing unit is slower than a transfer speed of the second data by the second processing unit.

3. The data transfer device according to claim 1, further comprising:
a monitoring unit that monitors information related to the second data or the third data,
wherein the monitoring unit is configured to:
monitor a data amount of the third data stored in the second storage unit, or
monitor a transfer speed difference between a transfer speed of the second data and a transfer speed of the third data, or
monitor the data amount of the third data stored in the second storage unit at predetermined intervals, or
store a number of frames in which an amount of data stored in the second storage unit becomes 0, or a timing at which the data amount of the third data becomes equal to or less than a threshold value when the data amount of the third data is equal to or less than the threshold value, and store the number of frames in which the amount of data stored in the second storage unit during exposure of the substrate becomes 0, a timing at which a transfer speed difference between a transfer speed of the second data and a transfer speed of the third data becomes equal to or less than a threshold value, or a timing at which the data amount of the third data becomes equal to or less than the threshold value when the data amount of the third data is equal to or less than the threshold value, or
display a warning on a display screen of the exposure device when the amount of data stored in the second storage unit becomes zero, when the transfer speed difference between the transfer speed of the second data and the transfer speed of the third data is equal to or less than a threshold value, or when the data amount of the third data is equal to or less than the threshold value, or
monitor a total data amount of the second data stored in each of the plurality of first memories, or
record the total data amount of the second data stored in each of the plurality of first memories, store a timing at which the total data amount of the second data becomes equal to or larger than a threshold value, compare the second data before being stored in the second processing unit with the third data transferred from the second processing unit to monitor presence or absence of different signals, and compare the second data before being stored in the second processing unit with the third data transferred from the third processing unit to monitor presence or absence of different signals, or
monitor presence or absence of different signals during exposure using the second data including an error detection code, or
monitor an elapsed time from an end of storing the second data in each of the first memories, and restore the second data in each of the first memories based on the elapsed time, or
monitor a total storage amount of the second data in each of the first memories, and restore the second data in each of the first memories based on the total storage amount of the second data, and monitor an elapsed time from an end of storing the second data in each of the first memories and the total storage amount of the second data in the first memory, and restore the second data in each of the first memories based on the elapsed time and the total storage amount of the second data.21.

4. The data transfer device according to claim 1,
wherein the first memory group includes the first memories in at least two, one of the first memories stores one piece of the second data of the plurality of pieces of second data, another one of the first memories stores another piece of the second data of the plurality of pieces of second data, and when the one of the first memories becomes unusable, the another one of the first memories stores the one piece of the second data and the another piece of the second data, or
wherein each of the first memories stores one piece of the second data of the plurality of pieces of second data in a first address and a second address that are two or more different addresses in the first memory, when a transfer speed of the one piece of the second data from the first address of the first memory is slower than a predetermined speed, the first memory suspends transfer of the one piece of the second data from the first address and transfers the one piece of the second data from the second address, or
wherein when a transfer speed of the second data from the first memory to the second storage unit is slower than a reference transfer speed, the first memory stores the second data in an address of a memory element different from an address of a memory element of the first memory that has been used, or
wherein each of the plurality of first memories is capable of correctly holding the first data to each of the plurality of first memories for a predetermined period even after a total data amount of the second data stored in each of the plurality of first memories exceeds a total bytes written (TBW) set in each of the plurality of first memories.

5. The data transfer device according to claim 1,
wherein a value equal to or greater than TBW is set as a lifetime for each of the plurality of first memories, or
wherein the second processing unit transfers an amount of data equal to or larger than a data amount determined by a predetermined formula to the second storage unit before exposure processing, and the predetermined formula is:
when a data transfer speed to a control board of the spatial light modulator is greater than a nominal value of a readout speed of the first memory,
$$Minimum required buffer capacity = \{ ( the data transfer speed to the control board of the spacial light modulator - a transfer speed assuming decrease in readout speed of the first memory \} ) \times an assumed time of time during which \\ the readout speed of the first memory decreases \} , and \qquad ( 1 )$$
when the data transfer speed to the control board of the spatial light modulator is less than the nominal value of the readout speed of the first memory,
$$Minimum required buffer capacity = \{ the data transfer speed to the control board of the spatial light modulator - the nominal value of the readout speed of the first memory \times a scanning time \} + \{ ( the data transfer speed to the control board of the spatial light modulator - a transfer speed assuming decrease in readout speed of the first memory ) \times assumed time of time during which the readout speed of the first memory decreases \} . \qquad ( 2 )$$

6. The data transfer device according to claim 1,
wherein the second processing unit transfers the second data to the third processing unit before exposure of the substrate, the third processing unit stores the third data in the second storage before exposure of the substrate, and the second processing unit transfers part of the second data to the third processing unit, or
wherein the first processing unit divides the plurality of elements into a plurality of regions to generate the second data, and generates the second data corresponding to each of the plurality of regions from the first data, or
wherein the first processing unit generates the second data for distributing and transferring first control data for controlling the plurality of elements at a first timing and second control data for controlling the plurality of elements at a second timing to each of the plurality of first memories, or
wherein the second processing unit includes a second memory group including a plurality of first memories, the second memory group being different from the first memory group, and (1) the first processing unit transfers the plurality of pieces of the second data to the second memory group, and the second processing unit transfers the plurality of pieces of the second data to the third processing unit while the substrate is being aligned or the exposure device is being calibrated, or (2) the first processing unit transfers a plurality of pieces of the second data to the plurality of first memories of the second memory group while the second processing unit is transferring the second data stored in the plurality of first memories of the first memory group to the third processing unit, or (3) the first processing unit transfers the second data corresponding to a second pattern different from a first pattern to be formed on the substrate to the plurality of first memories of the second memory group while the second processing unit is transferring the second data corresponding to the first pattern, which is stored in the plurality of first memories of the first memory group, to the third processing unit, or
wherein the data transfer device further comprises an erasure unit that periodically erases used data stored in the plurality of first memories.

7. The data transfer device according to claim 1, wherein the first data is bitmap data, the spatial light modulator is a digital micromirror device, and each of the plurality of elements is a micromirror.

8. An exposure device comprising:
the data transfer device according to claim 1;
an illumination unit that illuminates the spatial light modulator controlled based on the third data transferred from the data transfer device with illumination light; and
a plurality of projection units that form an image of exposure light modulated by the spatial light modulator on the substrate,
wherein the plurality of projection units adjust an imaging position on the substrate for each projection unit to form an image of the exposure light on the substrate.

9. The exposure device according to claim 8, wherein the plurality of projection units adjust an optical element included in each of the projection units to adjust the imaging position on the substrate.

10. A device comprising:
a plurality of first memories each storing data; and
a second memory that is connected to each of the plurality of first memories, and stores the plurality of pieces of data from the plurality of first memories.

11. The device according to claim 10, wherein each of the plurality of first memories includes a nonvolatile memory.

12. The device according to claim 10, wherein the second memory includes a random access memory.

13. The device according to claim 10,
wherein each of the plurality of first memories includes a nonvolatile memory, and
wherein the second memory includes a random access memory.

14. The device according to claim 10, wherein a capacity of the second memory is less than a capacity of the plurality of first memories.

15. The device according to claim 10,
wherein each of the plurality of first memories includes a nonvolatile memory,
wherein the second memory includes a random access memory, and
wherein a capacity of the second memory is less than a capacity of the plurality of first memories.

16. The device according to claim 10, further comprising:
a plurality of third memories each storing data,
wherein the second memory is connected to each of the plurality of third memories, and stores the plurality of pieces of data from the plurality of third memories, and
wherein the second memory is capable of switching a connection destination between the plurality of first memories and the plurality of third memories.

17. The device according to claim 10, further comprising:
a storage control board on which the plurality of first memories and the second memory are mounted.

18. The device according to claim 10, wherein the second memory is connected to a spatial light modulator so that second data based on the plurality of pieces of data from the second memory are transferred to the spatial light modulator.

19. An exposure device comprising:
a spatial light modulator including a plurality of elements that are individually controlled based on the second data transferred from the second memory of the device according to claim 18; and
a projection unit,
wherein light from an element in a first state among the plurality of elements enters a substrate through the projection unit, and light from an element in a second state among the plurality of elements enters other than the projection unit.

20. A device manufacturing method comprising:
exposing an exposure object using the exposure device according to claim 19; and
developing the exposed exposure object.
